(19) United States
(12) Patent Application Publication
(10) Pub. No.: US 2012/0056256 A1
(43) Pub. Date: Mar. 8, 2012

(54) SEMICONDUCTOR DEVICE AND METHOD FOR FORMING THE SAME

(75) Inventor: Noriaki MIKASA, Tokyo (JP)

(73) Assignee: ELPIDA MEMORY, INC., Tokyo (JP)

(21) Appl. No.: 13/223,990

(22) Filed: Sep. 1, 2011

(30) Foreign Application Priority Data
Sep. 6, 2010 (JP) 2010-199178

(51) Int. Cl. H01L 29/94; H01L 29/78

(52) U.S. Cl. 257/296; 257/329; 257/E29.345; 257/E29.262

(57) ABSTRACT

A semiconductor device includes a first semiconductor pillar, a second semiconductor pillar, and a first wiring. The first semiconductor pillar includes a first diffusion region. The second semiconductor pillar is adjacent to the first semiconductor pillar. The first wiring is positioned between the first and second semiconductor pillars. The first wiring has a first metal surface. The first metal surface has an ohmic contact with the first diffusion region.

### BACKGROUND OF THE INVENTION

1. Field of the Invention

The present invention generally relates to a semiconductor device and method for forming the same.

Priority is claimed on Japanese Patent Application No. 2010-199178, filed Sep. 6, 2010, the content of which is incorporated herein by reference.

2. Description of the Related Art

Integration density of semiconductor devices has been improved mainly by miniaturization of transistors. However, the miniaturization of the transistors approaches the limit thereof. If the size of the transistor is further shrunk, the transistor may not operate correctly because of a short channel effect or the like.

It is given a method for forming a transistor three-dimensionally by processing a semiconductor substrate three-dimensionally in view of the above. A vertical MOS (Metal Oxide Semiconductor) transistor, which is also called as a three-dimensional transistor, is known. The vertical MOS transistor has a pillar which extends vertical to a main surface of the semiconductor substrate. The pillar partly functions as a channel of the vertical MOS transistor. The vertical MOS transistor needs a smaller area than transistors in the related art. Electric current of the vertical MOS transistor can be easily controlled because the vertical MOS transistor is completely-depleted. The vertical MOS transistor can realize 4F² closest packed layout.

Japanese Unexamined Patent Applications, First Publications, Nos. JP-A-2009-10366 and JP-A-2009-164597 disclose that the vertical MOS transistor which is employed as a cell transistor in the semiconductor device, for example, a DRAM (Dynamic Random Access Memory). In this case, a lower impurity diffusion region formed below the pillar is generally connected to a bit line. An upper impurity diffusion region formed in an upper portion of the pillar is generally connected to a memory element (a cell capacitor in the DRAM). The lower impurity diffusion region functions as one of source and drain regions. The upper impurity diffusion region functions as the other of the source and drain regions. Since the memory element such as the cell capacitor is generally disposed over the cell transistor, the memory element is connected to the upper portion of the pillar, and the bit line is connected to the lower portion of the pillar. That is, it is necessary that the bit line is formed to be buried in the semiconductor substrate.

### SUMMARY

In one embodiment, a semiconductor device may include, but is not limited to, a first semiconductor pillar, a second semiconductor pillar, and a first wiring. The first semiconductor pillar includes a first diffusion region. The second semiconductor pillar is adjacent to the first semiconductor pillar. The first wiring is positioned between the first and second semiconductor pillars. The first wiring has a first metal surface. The first metal surface has an ohmic contact with the first diffusion region.

In another embodiment, a semiconductor device may include, but is not limited to, a semiconductor substrate, a first diffusion region, and a first wiring. The semiconductor substrate has a first groove. The first groove is defined by first and second side surfaces which face to each other. The first diffusion region is disposed in the semiconductor substrate. The first wiring is disposed between the first and second side surfaces. The first wiring has a first metal surface having an ohmic contact with the first diffusion region.

In still another embodiment, a semiconductor device may include, but is not limited to, a first pillar, a first impurity region, a second impurity region, a second pillar, and a bit line. The first pillar includes a first conductivity type impurity. The first impurity region is positioned in a side region of the first pillar. The first impurity region includes a second conductivity type impurity different in conductivity type from the first conductivity type impurity. The second impurity region is positioned on a top portion of the first pillar. The second impurity region includes the second conductivity type impurity. The second pillar is positioned adjacent to the first pillar. The second pillar includes the first conductivity type impurity. The bit line is positioned between the first and second pillars. The bit line is in contact with the first impurity region. The bit line is in contact with the second pillar.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary perspective view illustrating a memory cell array of a semiconductor device in accordance with one embodiment of the present invention;

FIG. 2 is a fragmentary plan view illustrating the memory cell array of the semiconductor device in accordance with one embodiment of the present invention;

FIG. 3A is a fragmentary cross sectional elevation view, taken along the A-A line of FIG. 2, illustrating the memory cell array of the semiconductor device in accordance with one embodiment of the present invention;

FIG. 3B is a fragmentary cross sectional elevation view, taken along the B-B line of FIG. 2, illustrating the memory cell array of the semiconductor device in accordance with one embodiment of the present invention;

FIG. 4A is a fragmentary cross sectional elevation view, taken along the A-A line of FIG. 2, illustrating the memory cell array in a step involved in a method of forming the semiconductor device of FIG. 1 in accordance with one embodiment of the present invention;

FIG. 4B is a fragmentary cross sectional elevation view, taken along the B-B line of FIG. 2, illustrating the memory cell array in a step involved in the method of forming the semiconductor device of FIG. 1 in accordance with one embodiment of the present invention;

FIG. 5A is a fragmentary cross sectional elevation view, taken along the A-A line of FIG. 2, illustrating the memory cell array in a step, subsequent to the step of FIG. 4A, involved in the method of forming the semiconductor device of FIG. 1 in accordance with one embodiment of the present invention;

FIG. 5B is a fragmentary cross sectional elevation view, taken along the B-B line of FIG. 2, illustrating the memory cell array in a step, subsequent to the step of FIG. 4B, involved in the method of forming the semiconductor device of FIG. 1 in accordance with one embodiment of the present invention;

FIG. 6A is a fragmentary cross sectional elevation view, taken along the A-A line of FIG. 2, illustrating the memory cell array in a step, subsequent to the step of FIG. 5A, involved in the method of forming the semiconductor device of FIG. 1 in accordance with one embodiment of the present invention;

FIG. 6B is a fragmentary cross sectional elevation view, taken along the B-B line of FIG. 2, illustrating the memory cell array in a step, subsequent to the step of FIG. 5B, involved in the method of forming the semiconductor device of FIG. 1 in accordance with one embodiment of the present invention;

FIG. 7A is a fragmentary cross sectional elevation view, taken along the A-A line of FIG. 2, illustrating the memory cell array in a step, subsequent to the step of FIG. 6A, involved in the method of forming the semiconductor device of FIG. 1 in accordance with one embodiment of the present invention;

FIG. 7B is a fragmentary cross sectional elevation view, taken along the B-B line of FIG. 2, illustrating the memory cell array in a step, subsequent to the step of FIG. 6B, involved in the method of forming the semiconductor device of FIG. 1 in accordance with one embodiment of the present invention;

FIG. 8A is a fragmentary cross sectional elevation view, taken along the A-A line of FIG. 2, illustrating the memory cell array in a step, subsequent to the step of FIG. 7A, involved in the method of forming the semiconductor device of FIG. 1 in accordance with one embodiment of the present invention;

FIG. 8B is a fragmentary cross sectional elevation view, taken along the B-B line of FIG. 2, illustrating the memory cell array in a step, subsequent to the step of FIG. 7B, involved in the method of forming the semiconductor device of FIG. 1 in accordance with one embodiment of the present invention;

FIG. 9A is a fragmentary cross sectional elevation view, taken along the A-A line of FIG. 2, illustrating the memory cell array in a step, subsequent to the step of FIG. 8A, involved in the method of forming the semiconductor device of FIG. 1 in accordance with one embodiment of the present invention;

FIG. 9B is a fragmentary cross sectional elevation view, taken along the B-B line of FIG. 2, illustrating the memory cell array in a step, subsequent to the step of FIG. 8B, involved in the method of forming the semiconductor device of FIG. 1 in accordance with one embodiment of the present invention;

FIG. 10A is a fragmentary cross sectional elevation view, taken along the A-A line of FIG. 2, illustrating the memory cell array in a step, subsequent to the step of FIG. 9A, involved in the method of forming the semiconductor device of FIG. 1 in accordance with one embodiment of the present invention;

FIG. 10B is a fragmentary cross sectional elevation view, taken along the B-B line of FIG. 2, illustrating the memory cell array in a step, subsequent to the step of FIG. 9B, involved in the method of forming the semiconductor device of FIG. 1 in accordance with one embodiment of the present invention;

FIG. 11A is a fragmentary cross sectional elevation view, taken along the A-A line of FIG. 2, illustrating the memory cell array in a step, subsequent to the step of FIG. 10A, involved in the method of forming the semiconductor device of FIG. 1 in accordance with one embodiment of the present invention;

FIG. 11B is a fragmentary cross sectional elevation view, taken along the B-B line of FIG. 2, illustrating the memory cell array in a step, subsequent to the step of FIG. 10B, involved in the method of forming the semiconductor device of FIG. 1 in accordance with one embodiment of the present invention;

FIG. 12A is a fragmentary cross sectional elevation view, taken along the A-A line of FIG. 2, illustrating the memory cell array in a step, subsequent to the step of FIG. 11A, involved in the method of forming the semiconductor device of FIG. 1 in accordance with one embodiment of the present invention;

FIG. 12B is a fragmentary cross sectional elevation view, taken along the B-B line of FIG. 2, illustrating the memory cell array in a step, subsequent to the step of FIG. 11B, involved in the method of forming the semiconductor device of FIG. 1 in accordance with one embodiment of the present invention;

FIG. 13A is a fragmentary cross sectional elevation view, taken along the A-A line of FIG. 2, illustrating the memory cell array in a step, subsequent to the step of FIG. 12A, involved in the method of forming the semiconductor device of FIG. 1 in accordance with one embodiment of the present invention;

FIG. 13B is a fragmentary cross sectional elevation view, taken along the B-B line of FIG. 2, illustrating the memory cell array in a step, subsequent to the step of FIG. 12B, involved in the method of forming the semiconductor device of FIG. 1 in accordance with one embodiment of the present invention;

FIG. 14A is a fragmentary cross sectional elevation view, taken along the A-A line of FIG. 2, illustrating the memory cell array in a step, subsequent to the step of FIG. 13A, involved in the method of forming the semiconductor device of FIG. 1 in accordance with one embodiment of the present invention;

FIG. 14B is a fragmentary cross sectional elevation view, taken along the B-B line of FIG. 2, illustrating the memory cell array in a step, subsequent to the step of FIG. 13B, involved in the method of forming the semiconductor device of FIG. 1 in accordance with one embodiment of the present invention;

FIG. 15A is a fragmentary cross sectional elevation view, taken along the A-A line of FIG. 2, illustrating the memory cell array in a step, subsequent to the step of FIG. 14A, involved in the method of forming the semiconductor device of FIG. 1 in accordance with one embodiment of the present invention;

FIG. 15B is a fragmentary cross sectional elevation view, taken along the B-B line of FIG. 2, illustrating the memory cell array in a step, subsequent to the step of FIG. 14B, involved in the method of forming the semiconductor device of FIG. 1 in accordance with one embodiment of the present invention;

FIG. 16A is a fragmentary cross sectional elevation view, taken along the A-A line of FIG. 2, illustrating the memory cell array in a step, subsequent to the step of FIG. 15A, involved in the method of forming the semiconductor device of FIG. 1 in accordance with one embodiment of the present invention;

FIG. 16B is a fragmentary cross sectional elevation view, taken along the B-B line of FIG. 2, illustrating the memory cell array in a step, subsequent to the step of FIG. 15B, involved in the method of forming the semiconductor device of FIG. 1 in accordance with one embodiment of the present invention;

FIG. 17A is a fragmentary cross sectional elevation view, taken along the A-A line of FIG. 2, illustrating the memory cell array in a step, subsequent to the step of FIG. 16A, involved in the method of forming the semiconductor device of FIG. 1 in accordance with one embodiment of the present invention;

FIG. 17B is a fragmentary cross sectional elevation view, taken along the B-B line of FIG. 2, illustrating the memory cell array in a step, subsequent to the step of FIG. 16B, involved in the method of forming the semiconductor device of FIG. 1 in accordance with one embodiment of the present invention;

FIG. 18A is a fragmentary cross sectional elevation view, taken along the A-A line of FIG. 2, illustrating the memory cell array in a step, subsequent to the step of FIG. 17A, involved in the method of forming the semiconductor device of FIG. 1 in accordance with one embodiment of the present invention;

FIG. 18B is a fragmentary cross sectional elevation view, taken along the B-B line of FIG. 2, illustrating the memory cell array in a step, subsequent to the step of FIG. 17B, involved in the method of forming the semiconductor device of FIG. 1 in accordance with one embodiment of the present invention;

FIG. 19A is a fragmentary cross sectional elevation view, taken along the A-A line of FIG. 2, illustrating the memory cell array in a step, subsequent to the step of FIG. 18A, involved in the method of forming the semiconductor device of FIG. 1 in accordance with one embodiment of the present invention;

FIG. 19B is a fragmentary cross sectional elevation view, taken along the B-B line of FIG. 2, illustrating the memory cell array in a step, subsequent to the step of FIG. 18B, involved in the method of forming the semiconductor device of FIG. 1 in accordance with one embodiment of the present invention;

FIG. 20A is a fragmentary cross sectional elevation view, taken along the A-A line of FIG. 2, illustrating the memory cell array in a step, subsequent to the step of FIG. 19A, involved in the method of forming the semiconductor device of FIG. 1 in accordance with one embodiment of the present invention;

FIG. 20B is a fragmentary cross sectional elevation view, taken along the B-B line of FIG. 2, illustrating the memory cell array in a step, subsequent to the step of FIG. 19B, involved in the method of forming the semiconductor device of FIG. 1 in accordance with one embodiment of the present invention;

FIG. 21A is a fragmentary cross sectional elevation view, taken along the A-A line of FIG. 2, illustrating the memory cell array of a semiconductor device in accordance with another embodiment of the present invention;

FIG. 21B is a fragmentary cross sectional elevation view, taken along the B-B line of FIG. 2, illustrating the memory cell array of the semiconductor device in accordance with another embodiment of the present invention;

FIG. 22A is a fragmentary cross sectional elevation view, taken along the A-A line of FIG. 2, illustrating the memory cell array in a step involved in a method of forming the semiconductor device in accordance with another embodiment of the present invention; and

FIG. 22B is a fragmentary cross sectional elevation view, taken along the B-B line of FIG. 2, illustrating the memory cell array in a step involved in the method of forming the semiconductor device of FIG. 1 in accordance with another embodiment of the present invention.

### DETAILED DESCRIPTION OF THE PREFERRED EMBODIMENTS

Before describing the present invention, the related art will be explained in order to facilitate the understanding of the present invention.

When a memory cell is configured by arranging a plurality of vertical MOS transistors, a short circuit between adjacent memory cells should be prevented.

Therefore, when the bit line is embedded in the semiconductor substrate, a connector, which is a bit contact, should be formed on a portion of one of side walls of the pillar. The connector electrically connects the lower impurity diffusion region which is formed below the vertical MOS transistor and the bit line.

For example, Japanese Unexamined Patent Application, First Publication, No. JP-A-2009-10366 discloses the following processes. An insulating film formed on one side wall of a bit trench is protected by a patterned photoresist. Then, the insulating film formed on the other side wall of the bit trench is selectively etched, thereby forming an opening in which the connector is positioned.

However, when the photoresist filled in the bit trench is patterned by the known exposure method, the resolution of the photoresist is lowered since the deeper the bit trench is, the thicker the photoresist is.

It is difficult to accurately pattern the photoresist covering the insulating film formed on one side wall of the bit trench in minute memory cells in and after the generation of a 50-nm design rule. It is difficult to form a miniaturized conductor electrically connected to the lower impurity diffusion region, which is a conductor formed by a bit line and a bit contact in this case, by the method described in Japanese Unexamined Patent Application, First Publication, No. JP-A-2009-10366.

Japanese Unexamined Patent Application, First Publication, No. JP-A-2009-164597 discloses a method for forming a wiring with an impurity diffusion region. In this case, it is difficult to form a high performance semiconductor device because of a high resistivity of the wiring.

As described above, it is difficult to reduce a resistivity of the bit line connected to the lower impurity diffusion region and to miniaturize the bit line in order to form a buried bit line in the semiconductor substrate by the methods disclosed in Japanese Unexamined Patent Applications, First Publication, Nos. JP-A-2009-10366 and JP-A-2009-164597.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a first semiconductor pillar, a second semiconductor pillar, and a first wiring. The first semiconductor pillar includes a first diffusion region. The second semiconductor pillar is adjacent to the first semiconductor pillar. The first wiring is positioned between the first and second semiconductor pillars. The first wiring has a first metal surface. The first metal surface has an ohmic contact with the first diffusion region.

In some cases, the semiconductor device may include, but is not limited to, the first wiring having a second metal surface having a Schottky barrier with the second semiconductor pillar.

In some cases, the semiconductor device may include, but is not limited to, the first and second metal surfaces positioned on opposite sides with respect to the first wiring. The first and second metal surfaces are distanced in a first direction perpendicular to a second direction substantially in which the first wiring extends.

In some cases, the semiconductor device may include, but is not limited to, the first diffusion region being different in conductivity type from the first and second semiconductor pillars.

In some cases, the semiconductor device may include, but is not limited to, the first diffusion region being higher in impurity concentration from the first and second semiconductor pillars.

In some cases, the semiconductor device may further include, but is not limited to, a first insulating film between the first wiring and each of the first and second semiconductor pillars. The first insulating film has a first opening in which the first metal surface is in the ohmic contact with the first diffusion region. The first insulating film has a second opening in which the second metal surface is in the Schottky barrier with the second semiconductor pillar.

In some cases, the semiconductor device may further include, but is not limited to, the first wiring including a first metal layer having the first and second metal surfaces, and a second metal layer separated by the first metal layer from the first diffusion region and from the second semiconductor pillar. The first metal layer is higher in resistivity than the second metal layer.

In some cases, the semiconductor device may further include, but is not limited to, an insulating region in the second semiconductor pillar. The first wiring has a second metal surface in contact with the second insulating film.

In some cases, the semiconductor device may include, but is not limited to, the first and second metal surfaces being positioned on opposite sides with respect to the first wiring. The first and second metal surfaces are distanced in a first direction perpendicular to a second direction substantially in which the first wiring extends.

In some cases, the semiconductor device may further include, but is not limited to, a second insulating film between the first wiring and each of the first and second semiconductor pillars. The second insulating film has a first opening in which the first metal surface is in the ohmic contact with the first diffusion region. The first insulating film has a second opening in which the second metal surface is in contact with the insulating region.

In some cases, the semiconductor device may further include, but is not limited to, a second diffusion region on the top of the first semiconductor pillar and a capacitor coupled to the second diffusion region.

In another embodiment, a semiconductor device may include, but is not limited to, a semiconductor substrate, a first diffusion region, and a first wiring. The semiconductor substrate has a first groove. The first groove is defined by first and second side surfaces which face to each other. The first diffusion region is disposed in the semiconductor substrate. The first wiring is disposed between the first and second side surfaces. The first wiring has a first metal surface having an ohmic contact with the first diffusion region.

In some cases, the semiconductor device may include, but is not limited to, the first wiring having a second metal surface having a Schottky barrier with the second side surface.

In some cases, the semiconductor device may further include, but is not limited to, a first insulating film between the first wiring and each of the first and second semiconductor pillars. The first insulating film has a first opening in which the first metal surface is in the ohmic contact with the first diffusion region. The first insulating film has a second opening in which the second metal surface is in the Schottky barrier with the second semiconductor pillar.

In some cases, the semiconductor device may further include, but is not limited to, an insulating region in the second semiconductor pillar. The first wiring has a second metal surface in contact with the second insulating film.

In some cases, the semiconductor device may further include, but is not limited to, a second insulating film between the first wiring and each of the first and second semiconductor pillars. The second insulating film has a first opening in which the first metal surface is in the ohmic contact with the first diffusion region. The first insulating film has a second opening in which the second metal surface is in contact with the insulating region.

In still another embodiment, a semiconductor device may include, but is not limited to, a first pillar, a first impurity region, a second impurity region, a second pillar, and a bit line. The first pillar includes a first conductivity type impurity. The first impurity region is positioned in a side region of the first pillar. The first impurity region includes a second conductivity type impurity different in conductivity type from the first conductivity type impurity. The second impurity region is positioned on a top portion of the first pillar. The second impurity region includes the second conductivity type impurity. The second pillar is positioned adjacent to the first pillar. The second pillar includes the first conductivity type impurity. The bit line is positioned between the first and second pillars. The bit line is in contact with the first impurity region. The bit line is in contact with the second pillar.

In some cases, the semiconductor device may further include, but is not limited to, a capacitor coupled to the second impurity region.

In some cases, the semiconductor device may include, but is not limited to, the bit line including a metal film in contact with the second pillar.

In some cases, the semiconductor device may include, but is not limited to, the second pillar including a semiconductor pillar portion and an insulating region in a side region of the semiconductor pillar portion. The insulating region is in contact with the bit line.

Hereinafter, a semiconductor device according to an embodiment of the invention will be described in detail with reference to the drawings. In the drawings used for the following description, to easily understand characteristics, there is a case where characteristic parts are enlarged and shown for convenience' sake, and ratios of constituent elements may not be the same as in reality. Materials, sizes, and the like exemplified in the following description are just examples. The invention is not limited thereto and may be appropriately modified within a scope which does not deviate from the concept of the invention.

### First Embodiment

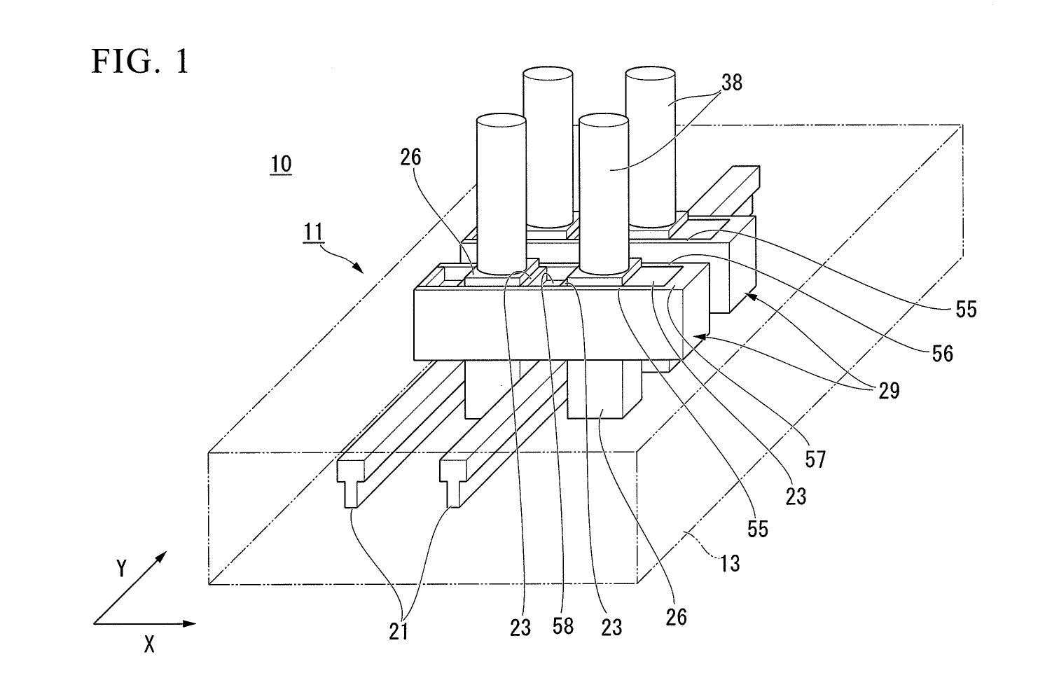

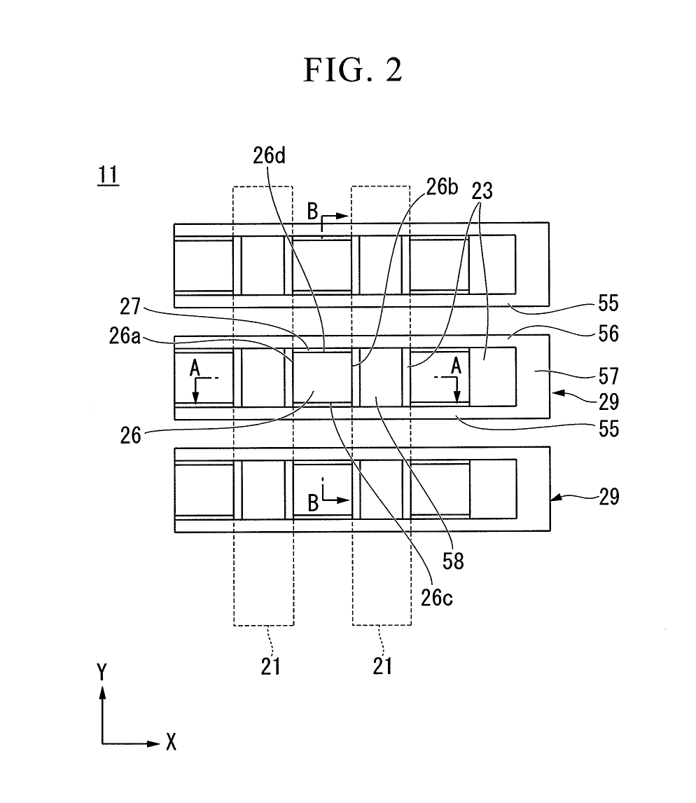

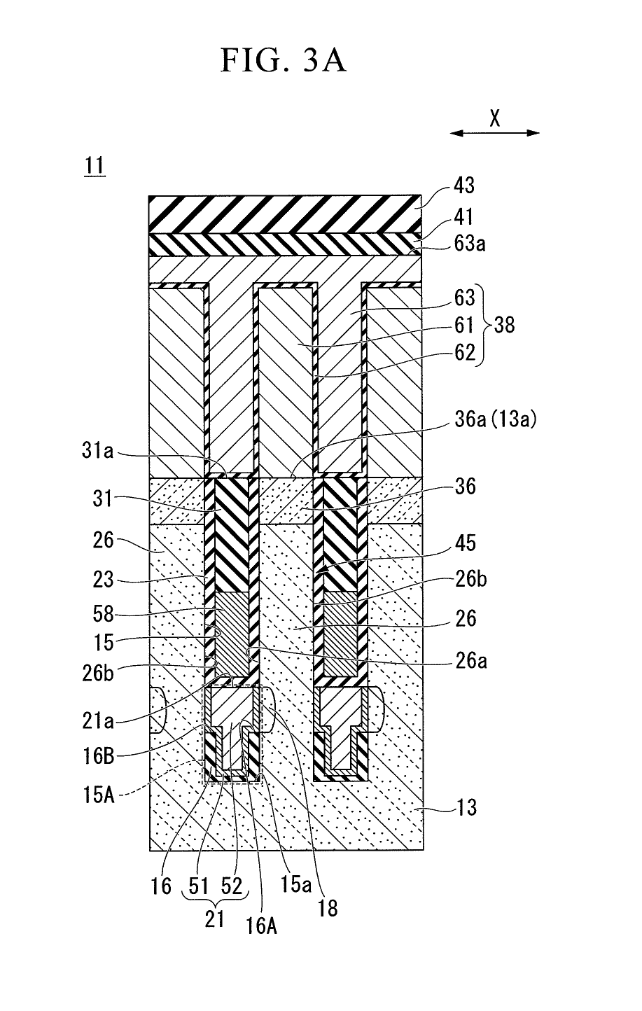

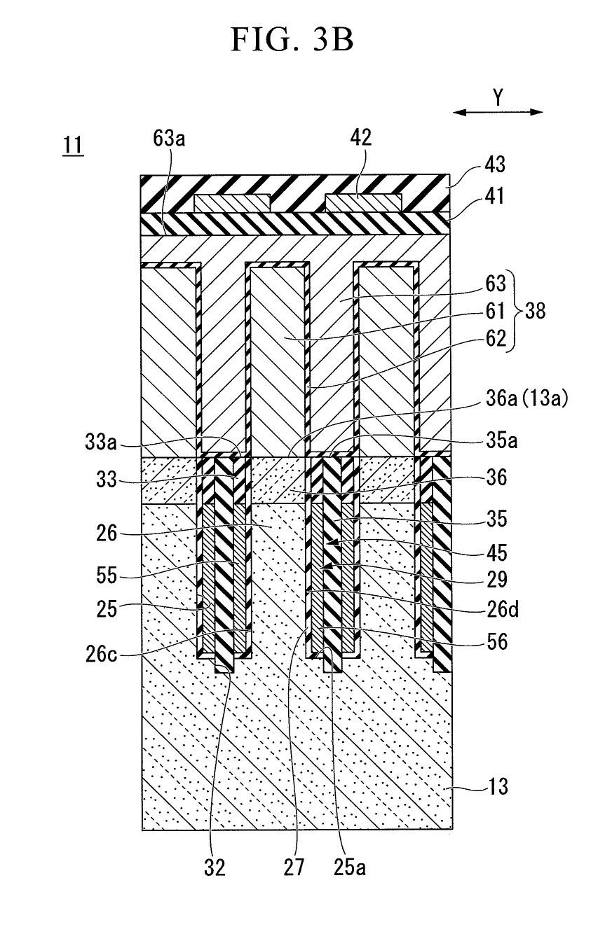

FIG. 1 is a fragmentary perspective view illustrating a memory cell array of a semiconductor device in accordance with one embodiment of the present invention. FIG. 2 is a fragmentary plan view illustrating the memory cell array of the semiconductor device in accordance with one embodiment of the present invention. FIG. 3A is a fragmentary cross sectional elevation view, taken along the A-A line of FIG. 2, illustrating the memory cell array of the semiconductor device in accordance with one embodiment of the present invention. FIG. 3B is a fragmentary cross sectional elevation view, taken along the B-B line of FIG. 2, illustrating the memory cell array of the semiconductor device in accordance with one embodiment of the present invention.

In FIGS. 1, 2, and 3A, an X-direction corresponds to an extending direction of gate electrodes 55 and 56. In FIGS. 1, 2, and 3B, a Y-direction corresponds to an extending direction of a buried bit line 21 crossing the gate electrodes 55 and 56.

In FIG. 1, only a semiconductor substrate 13, the buried bit line 21, a word line 29, a pillar 26, an insulating film 23, and a capacitor 38 are illustrated among elements forming a memory cell array 11, which are illustrated in FIGS. 3A and 3B, to simplify an explanation of the present embodiment.

In FIG. 2, only the buried bit line 21, the word line 29, the pillar 26, the insulating film 23, and a gate insulating film 27 are illustrated among the elements forming a memory cell array 11, which are illustrated in FIGS. 3A and 3B, to simplify the explanation of the present embodiment.

The same parts as those of the memory cell array 11 in FIGS. 1 and 2 are denoted by the same reference numerals in FIGS. 3A and 3B. In FIGS. 1 through 3B, a DRAM (Dynamic Random Access Memory) is explained as an example of a semiconductor device 10 of the first embodiment, but is not limited thereto.

As shown in FIGS. 1 through 3B, the semiconductor device 10 according to the first embodiment may include, but is not limited to, a memory cell region and a peripheral circuit region. The memory cell array 11 is formed in the memory cell region. A peripheral circuit (not shown) disposed in a periphery of the memory cell region is formed in the peripheral circuit region. A transistor for the peripheral circuit (not shown) and the like are formed in the peripheral circuit region.

A structure of the memory cell array 11 will be described with reference to FIGS. 1 through 3B.

The memory cell array 11 may include, but is not limited to, the semiconductor substrate 13, a first groove 15, an insulating film 16, the insulating film 23, a lower impurity diffusion region 18, the buried bit line 21, a second groove 25, the pillar 26, the gate insulating film 27, the word line 29, first and second buried insulating films 31 and 35, a separation groove 32, a liner film 33, an upper impurity diffusion region 36, the capacitor 38, interlayer insulating films 41 and 43, and a wiring 42. The capacitor 38 is a memory element. In an outer circumference of the memory cell region, an isolation region (not shown) is disposed. The memory cell region is electrically isolated from the peripheral circuit by the isolation region.

As shown in FIGS. 3A and 3B, the semiconductor substrate 13 is a substrate including a first impurity having a different conductivity type from that of a second impurity included in the lower impurity diffusion region 18. A concentration of the first impurity in the semiconductor substrate 13 is lower than that of the second impurity in the lower impurity diffusion region 18.

As the semiconductor substrate 13, a silicon substrate including a low concentration (approximately 5E12-5E13 atoms/cm² as an ion implantation dosage) of a p-type impurity may be used. The concentration of the p-type impurity may be adjusted to a predetermined value by forming a p-type well in the memory cell region in advance.

In the present embodiment, the explanation will be made in the case where the silicon substrate (silicon wafer) including the low concentration of the p-type impurity is used as the semiconductor substrate 13, but is not limited thereto.

The isolation region (not shown) is disposed to surround the memory cell region on the semiconductor substrate 13. The isolation region includes an isolation groove (not shown) and an isolation insulating film (not shown) filling the isolation groove. The semiconductor substrate 13 includes the memory cell region disposed inside the isolation region. The semiconductor substrate 13 may include a plurality of memory cell regions.

A silicon oxide film (SiO₂ film) may be used as the isolation insulating film. A structure of the above described isolation region is generally called as STI (Shallow Trench Isolation). The memory cell region is an active region electrically isolated by the isolation region.

As shown in FIG. 3A, the first grooves 15 are formed by partially etching a main surface 13a of the semiconductor substrate 13. The first grooves 15 are provided for forming the buried bit line 21. The first grooves 15 extend in the Y-direction (first direction) and are arranged at a predetermined interval in the X-direction (second direction).

The first groove 15 is defined by inside walls including a bottom surface 15a of the first groove 15 and a pair of side wall surfaces 26a and 26b of the plurality of pillars 26 which are aligned in the Y-direction.

A first wall surface of the first groove 15 corresponds to the side wall surface 26a of the pillar 26. A second wall surface of the first groove 15 corresponds to the other side wall surface 26b of the pillar 26.

As shown in FIG. 3A, the insulating film 16 is provided on the bottom surface 15a of the first groove 15, the side wall surfaces 26a and 26b of the pillar 26 in a bottom portion 15A of the first groove 15. The insulating film 16 has first and second openings 16A and 16B. The lower impurity diffusion region 18 formed on the side wall surface 26a of the pillar 26 is shown through the first opening 16A. The side wall surface 26b of the pillar 26 is shown through the second opening 16B. The second opening 16B is provided to be opposed to the first opening 16A. The insulating film 16 may be, but is not limited to, a silicon oxide film (SiO₂ film).

As described above, the insulating film 16 having the first and second openings 16A and 16B is provided. The side wall surface 26a of the pillar 26 is shown through the first opening 16A. The side wall surface 26b of the pillar 26 is shown through the second opening 16B opposed to the first opening 16A. By doing this, it is not necessary to form an opening on one side using the photoresist film. Since the first and second openings 16A and 16B can be formed in the same step, the first and second openings 16A and 16B can be processed easily. Therefore, the buried bit line 21 which is miniaturized can be formed in the first groove 15 formed in the semiconductor substrate 13 to be in contact with the lower impurity diffusion region 18.

As shown in FIG. 3A, the lower impurity diffusion region 18 is formed on the side wall surface 26a of the pillar 26 which is shown through the first opening 16A. The lower impurity diffusion region 18 includes a high concentration of an n-type impurity, for example, arsenic (As). The lower impurity diffusion region 18 functions as one of source and drain regions. In the present embodiment, the lower impurity diffusion region 18 may function as the drain region for convenience' sake. A concentration of the n-type impurity included in the lower impurity diffusion region 18 is higher than that of the p-type impurity included in the semiconductor substrate 13.

As shown in FIG. 3A, the buried bit line 21 may be, but is not limited to, a lamination (metal film) of first and second metal films 51 and 52. The first metal film 51 functions as a barrier film. The second metal film 52 is lower in conductivity than the first metal film 51.

When the buried bit line 21 is formed of only the metal film, specifically, the first and second metal films 51 and 52, the buried bit line 21 can have a lower resistivity than in the case where the bit line is formed by an impurity diffusion region. By doing this, a high-performance semiconductor device can be achieved.

The first metal film 51 is thinner than the second metal film 52. The first metal film 51 is disposed on a surface of the insulating film 16 and in the first and second openings 16A and 16B.

The first metal film 51 is in contact with the lower impurity diffusion region 18, which includes the high concentration of the n-type impurity, through the opening 16A.

When the first metal film 51 includes titanium (Ti) or the like, the first metal film 51 tends to make an ohmic contact with the lower impurity diffusion region 18 including the high concentration of the n-type impurity because of the work function of the first metal film 51. Further, when increasing the concentration of the n-type impurity, a quantum tunneling becomes dominant between the first metal film 51 and the lower impurity diffusion region 18. In this case, the first metal film 51 makes an ohmic contact with the lower impurity diffusion region 18. By virtue of this, the preferable conductivity state is maintained between the buried bit line 21 and the lower impurity diffusion region 18.

The first metal film 51 is in contact with the side wall surface 26b of the pillar 26, which functions as the channel, through the second opening 16B. That is, the first metal film 51 is in contact with the semiconductor substrate 13, which include silicon and the low concentration of the p-type impurity (approximately 5E12-5E13 atoms/cm² as an ion implantation dosage), through the second opening 16B.

In the case where the first metal film 51 includes titanium (Ti) or the like, a Schottky barrier tends to be formed because of the work function of the first metal film 51 when the first metal film 51 contacts the semiconductor substrate 13 including the p-type impurity. Further, when the concentration of the p-type impurity is set low, the quantum tunneling at the contact portion of the first metal film 51 and the semiconductor substrate is suppressed. In this case, the Schottky barrier is formed between the first metal film 51 and the semiconductor substrate 13.

In the memory cell employing the n-type MOS (Metal Oxide Semiconductor) transistor, while the semiconductor substrate 13 is maintained to be grounded (0V) or to have a negative voltage (for example, −0.2V), the buried bit line 21 is operated with a voltage swing from the ground voltage (0V) to a positive voltage (for example, +1.5V).

When the buried bit line 21 in contact with the lower impurity diffusion region 18 and the semiconductor substrate 13 is applied to the n-type MOS transistor, an isolation state in which electric current is blocked between the buried bit line 21 applied with the positive voltage and the semiconductor substrate 13 maintained to be grounded (0V) or to have a negative voltage can be maintained by a rectification behavior of the Schottky barrier.

When the p-type well (not shown) is formed in the memory cell region of the semiconductor substrate 13 in advance, a similar effect of the Schottky barrier can be obtained by setting an ion implantation dosage a low value such as approximately 5E12-5E13 atoms/cm².

By doing this, the buried bit line 21 is electrically connected to only the lower impurity diffusion region 18 in the semiconductor device 10 according to the first embodiment.

The first metal film 51 may include, but is not limited to, a lamination formed by laminating a titanium (Ti) film and a titanium nitride (TiN) film in this order, for example. The first metal film 51 may be the lamination formed by laminating a titanium (Ti) film and a titanium nitride (TiN) film in this order. In this case, the lower titanium film makes a junction between the buried bit line 21 and the semiconductor substrate 13.

The second metal film 52 covers an inner surface of the first metal film 51. The second metal film 52 fills the bottom portion 15A of the first groove 15, which includes the first and second openings 16A and 16B. The insulating film 16 and the first metal film 51 is interposed between the second metal film 52 and the surfaces of the bottom portion 15A of the first groove 15. The second metal film 52 may include, but is not limited to, a tungsten (W) film, for example. The second metal film 52 may be the tungsten (W) film.

The buried bit line 21 is T-shaped in a cross sectional view. A top surface 21a of the buried bit line 21 is flat.

As shown in FIG. 3A, the insulating film 23 covers the top surface 21a of the buried bit line 21 and the side wall surfaces 26a and 26b of the pillar 26, which are positioned above the buried bit line 21. The insulating film 23 may include, but is not limited to, a SiON film, for example. The insulating film 23 may be the SiON film.

As shown in FIGS. 3A and 3B, the second grooves 25 are formed by partially etching the main surface 13a of the semiconductor substrate 13. The second grooves 25 extend in the X-direction. Each second groove 25 is defined by inside walls including wall surfaces (side wall surfaces 26c and 26d of the pillar 26 facing each other). The plurality of second grooves 25 are sequentially arranged in the Y-direction. The second grooves 25 are provided for forming the gate electrodes 55 and 56. The second groove 25 is shallower than the first groove 15.

As shown in FIGS. 3A and 3B, the pillar 26 is surrounded by the first and second grooves 15 and 25 and has a pillar-shape. The pillar 26 has the side wall surfaces 26a, 26b, 26c, and 26d. The side wall surfaces 26a and 26b face each other in the X-direction. The side wall surfaces 26c and 26d face each other in the Y-direction.

The plurality of pillars 26 are provided at a predetermined interval. The pillar 26 is formed of the semiconductor substrate 13. The pillar 26 is formed by partially etching the main surface 13a of the semiconductor substrate 13 and processing the first and second grooves 15 and 25. A portion of the pillar 26, which is positioned between the upper impurity diffusion region 36 and the lower impurity diffusion region 18 functions as a channel.

The vertical MOS transistor 45 is formed by providing the pillar 26 with the lower impurity diffusion region 18, the upper impurity diffusion region 36, the gate insulating film 27, and the pair of gate electrodes 55 and 56 which will be described later. The plurality of vertical MOS transistors 45 are arranged in a matrix in the memory cell array 11.

When the vertical MOS transistor 45 is configured to have a small area and to be completely-depleted, an OFF-state can be maintained without setting a high threshold voltage. Thereby, the electric current can be easily controlled. In the memory cell array 11, the 4F² closest packed layout (F is the minimum dimension) can be realized by providing the plurality of the vertical MOS transistors 45.

As shown in FIG. 3B, the gate insulating film 27 covers the side wall surfaces 26c and 26d of the plurality of pillars 26, which include side surfaces of the upper impurity diffusion region 36, and a bottom surface 25a of the second groove 25.

As the gate insulating film 27, a single silicon oxide film (SiO₂ film), a nitrided silicon oxide film (SiON film), a lamination formed by laminating a silicon nitride film (SiN film) or a high dielectric film (High-k film) on the silicon oxide film (SiO₂ film), a single high dielectric film, or the like may be used, for example. However, the gate insulating film 27 is not limited thereto.

As shown in FIG. 1, the word line 29 may include, but is not limited to, the pair of gate electrodes 55 and 56, an electrode end connector 57, and a connector 58.

As shown in FIGS. 1, 2, and 3B, the gate electrode 55 extends in the X-direction. The gate electrode 55 is provided on the side wall surface 26c of the plurality of pillars 26 while the gate insulating film 27 is interposed between the gate electrode 55 and the side wall surface 26c. The gate electrode 56 extends in the X-direction. The gate electrode 56 is provided on the side wall surface 26d of the plurality of pillars 26 while the gate insulating film 27 is interposed between the gate electrode 56 and the side wall surface 26d. The gate electrode 56 is opposed to the gate electrode 55 via the gate insulating film 27 and the plurality of pillars 26.

As shown in FIGS. 1 and 2, the electrode end connectors 57 are provided at both ends of the gate electrodes 55 and 56, respectively. The electrode end connectors 57 are united to the ends of the gate electrodes 55 and 56. In FIGS. 1 and 2, only the electrode end connector 57 provided at single ends of the gate electrodes 55 and 56.

As shown in FIGS. 1 and 3A, the connector 58 is provided in the first groove 15 between the gate electrodes 55 and 56 while the insulating film 23 is interposed between the connector 58 and the side wall surfaces 26a and 26b. The connector 58 is positioned over the buried bit line 21 while the insulating film 23 is interposed between the connector 58 and the buried bit line 21.

One end of the connector 58 is united to the gate electrode 55 and the other end of the connector 58 is united to the gate electrode 56. Since the word line 29 has a ladder shape in plan view (FIG. 2) by providing the connector 58, an increase of resistance caused by a length of the word line 29 in the X-direction can be suppressed.

The word line 29 is formed by a conductive film. The word line 29 may include, but is not limited to, a lamination formed by laminating a titanium (Ti) film, a titanium nitride (TiN) film, and a tungsten (W) film in this order.

As shown in FIG. 3A, the buried insulating film 31 fills the first groove 51 above the connector 58 to bury the connector 58. The insulating film 23 is interposed between the buried insulating film 31 and the side wall surfaces 26a and 26b. A top surface 31a of the buried insulating film 31 is flat and aligned with the main surface 13a of the semiconductor substrate 13. As the buried insulating film 31, an insulating film having a burying property and being dense may be used. Specifically, as the buried insulating film 31, a silicon oxide film (SiO₂ film) formed by HDP (High Density Plasma) may be used. However, the buried insulating film 31 is not limited thereto.

As shown in FIG. 3B, the separation groove 32 extends in the X-direction and is formed in the second groove 25. The separation groove 32 is narrower in width in the Y-direction than the second groove 25.

The separation groove 32 divides a conductive film (not shown) buried in the second groove 25 into two parts to form the gate electrodes 55 and 56. The conductive film will be processed into the word line 29.

Therefore, the separation groove 32 is deeper than the second groove 25 to certainly divide the conductive film to be processed into the word line 29.

As shown in FIG. 3B, the liner films 33 are formed in the second groove 25. The liner films 33 are formed on the gate electrodes 55 and 56, respectively as side walls. The liner film 33 may include, but is not limited to, a SiON film, for example. The liner film 33 may be the SiON film. A top surface 33a of the liner film 33 is flat and aligned with the main surface 13a of the semiconductor substrate 13.

As shown in FIG. 3B, the buried insulating film 35 fills the separation groove 32. The buried insulating film 35 covers side walls of the gate electrodes 55 and 56 and side walls of the liner films 33. A top surface 35a of the liner film 35 is flat and aligned with the main surface 13a of the semiconductor substrate 13.

As shown in FIGS. 3A and 3B, the upper impurity diffusion region 36 is formed in an upper end portion of the pillar 26. A bottom of the upper impurity diffusion region 36 is substantially aligned with the top surface of the gate electrodes 55 and 56. A top surface 36a of the upper impurity diffusion region 36 is substantially aligned with the main surface 13a of the semiconductor substrate 13. The upper impurity diffusion region 36 includes a high concentration of an n-type impurity, for example, arsenic (As). The upper impurity diffusion region 36 functions as the other of the source and drain regions. In the present embodiment, the upper impurity diffusion region 36 may function as the source region for convenience' sake.

As shown in FIGS. 3A and 3B, the capacitor 38 is provided on the upper impurity diffusion region 36. Each of the plurality of pillars 26 is provided with one capacitor 38. That is, the memory cell array 11 includes the plurality of capacitors 38.

The capacitor 38 includes a lower electrode 61, a capacitor insulating film 62, and an upper electrode 63. The lower electrode 61 is disposed on the upper impurity diffusion region 36. The capacitor insulating film 62 is formed on the plurality of lower electrodes 61 to cover a surface of the lower electrode 61. The upper electrode 63 covers a surface of the capacitor insulating film 62. The upper electrode 63 fills gaps between the plurality of lower electrodes 61 on which the capacitor insulating film 62 is formed. The upper electrode 63 is common to the plurality of lower electrodes 61.

The lower electrode 61 may include, but is not limited to, a lamination formed by laminating a titanium film and a titanium nitride film in this order, for example. The lower electrode 61 may be the lamination formed by laminating the titanium film and the titanium nitride film in this order. In this case, a thickness of the titanium film may be, but is not limited to, 10 nm.

The capacitor insulating film 62 may include, but is not limited to, a lamination formed by laminating an aluminum oxide film (Al₂O₃ film) and a zirconium oxide film (ZrO₂ film) in this order. The capacitor insulating film 62 may be the lamination formed by laminating the aluminum oxide film (Al₂O₃ film) and the zirconium oxide film (ZrO₂ film) in this order.

A top surface 63a of the upper electrode 63 is flat. The upper electrode 63 may include, but is not limited to, a metal film such as a ruthenium (Ru) film, a tungsten (W) film, a titanium nitride film, a lamination of the metal film and a polysilicon film or the like. The upper electrode 63 may be the metal film such as the ruthenium (Ru) film, the tungsten (W) film, the titanium nitride film, the lamination of the metal film and the polysilicon film or the like.

As shown in FIGS. 3A and 3B, the interlayer insulating film 41 is provided on the top surface 63a of the upper electrode 63. The interlayer insulating film 41 may include, but is not limited to, a silicon oxide film (SiO₂ film). The interlayer insulating film 41 may be the silicon oxide film (SiO₂ film).

The wiring 42 is provided on the interlayer insulating film 41. The wiring 42 is electrically connected to the upper electrode 63 formed thereunder.

The interlayer insulating film 43 is provided on the interlayer insulating film 41 to cover the wiring 42. The interlayer insulating film 43 may include, but is not limited to, a silicon oxide film (SiO₂ film). The interlayer insulating film 43 may be the silicon oxide film (SiO₂ film).

According to the semiconductor device 10 of the first embodiment, the buried bit line 21 is provided in the bottom portion 15A of the first groove 15 while the insulating film 16 is interposed between the buried bit line 21 and the bottom portion 15A. The buried bit line 21 fills the first and second openings 16A and 16B of the insulating film 16. The buried bit line 21 is in contact with the lower impurity diffusion region 18 and the side wall surface 26b of the pillar 26 (the semiconductor substrate 13 including the low concentration of the p-type impurity). The buried bit line 21 includes the metal film (the first and second metal films 51 and 52). By providing the above described buried bit line 21, the buried bit line 21 can be electrically connected via ohmic contact to the lower impurity diffusion region 18 including the high concentration of the n-type impurity. Also, the buried bit line 21 and the side wall surface 26b of the pillar 26 (the semiconductor substrate 13) can be electrically isolated from each other by the Schottky barrier.

Therefore, if the insulating film 16 formed on the side wall surfaces 26a and 26b of the pillar 26 has the openings which are specifically the first and second openings 16A and 16B, the buried bit line 21 is not electrically connected to the side wall surface 26b of the pillar 26 (the semiconductor substrate 13).

In the related art, an opening is formed on only one side wall surface of a pillar. In order to avoid simultaneously forming two openings opposed to each other in the insulating film 16, a photoresist film protecting the other side wall surface of the pillar is necessary. According to the present embodiment, there is no need to form the photoresist film. Therefore, the buried bit line 21 which is miniaturized can be formed easily in the first groove 15.

Since the buried bit line 21 is the metal film, the buried bit line 21 is lower in resistivity than in the case where the buried bit line is formed by an impurity diffusion region or a polysilicon film. Therefore, a high-performance semiconductor device can be realized.

The buried bit line 21 is in direct contact with the lower impurity diffusion region 18 without forming a bit contact (not shown) formed of a poly silicon film between the buried bit line 21 and the lower impurity diffusion region 18. By doing this, a contact resistance between the buried bit line 21 and the lower impurity diffusion region 18 can be reduced, thereby realizing a high-performance semiconductor device.

According to the semiconductor device 10 of the first embodiment, a silicide layer (not shown) may be formed on the upper impurity diffusion region 36. That is, the silicide layer may be formed between the capacitor 38 and the upper impurity diffusion region 36.

By providing the silicide layer (not shown) between the capacitor 38 and the upper impurity diffusion region 36, a contact resistance between the capacitor 38 and the upper impurity diffusion region 36 can be reduced.

The silicide layer may include, but is not limited to, a titanium silicide (TiSi₂) film. The silicide layer may be the titanium silicide (TiSi₂) film. The titanium silicide film has a low resistance among silicide layers. Also, even when a natural oxide film (silicon oxide film (SiO₂ film)) is formed on the top surface 36a of the upper impurity diffusion region 36, a stable solid state reaction between the silicon oxide film and the titanium silicide film (titanium reduces the silicon oxide film) is progressed.

In this case, the titanium (Ti) film is used as the lower electrode 61, and the TiSi₂ film is formed by depositing the titanium film on the top surface 36a of the upper impurity diffusion region 36 and reacting the titanium film with the upper impurity diffusion region 36 by CVD (Chemical Vapor Deposition).

Also, instead of providing the silicide layer (not shown), a contact plug (not shown) including a polysilicon film or a tungsten (W) film may be formed between the lower electrode 61 of the capacitor 38 and the upper impurity diffusion region 36 to electrically connect the lower electrode 61 and the upper impurity diffusion region 36.

According to the semiconductor device 10 of the first embodiment, the word line 29 provided with the connector 58 is described, but is not limited thereto. The connector 58 is not necessarily provided.

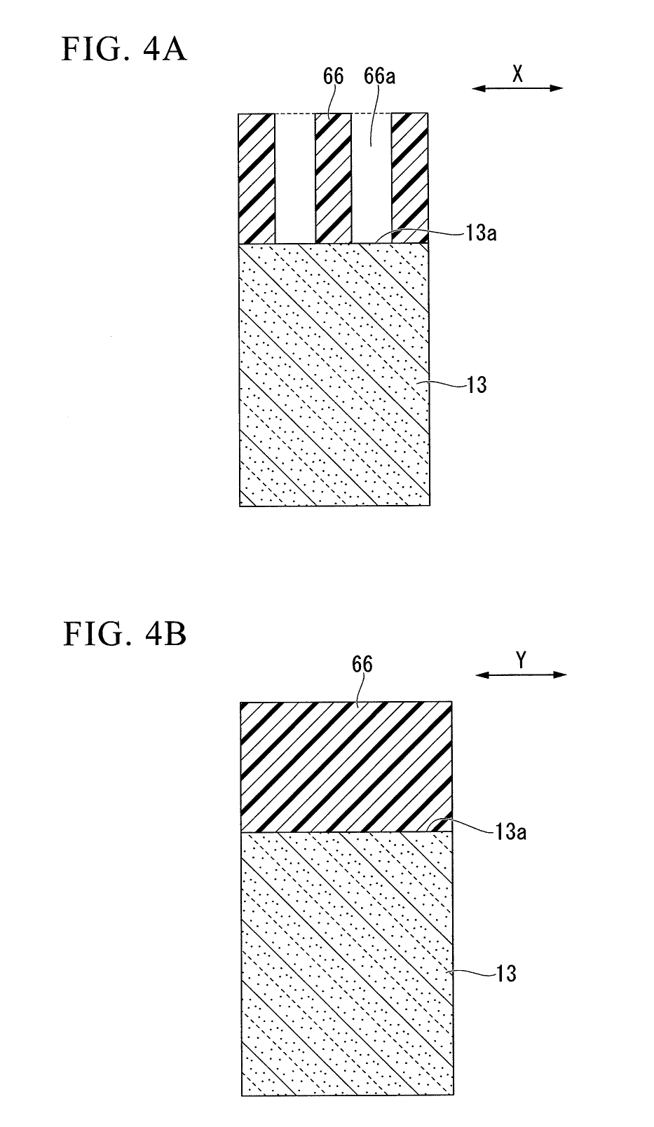

FIGS. 4A through 20B are fragmentary cross sectional elevation views illustrating the memory cell array in steps involved in a method of forming the semiconductor device of FIG. 1 in accordance with one embodiment of the present invention.

FIGS. 4A, 5A, 6A, 7A, 8A, 9A, 10A, 11A, 12A, 13A, 14A, 15A, 16A, 17A, 18A, 19A, and 20A are fragmentary cross sectional elevation views, taken along the A-A line of FIG. 2, and correspond to the fragmentary cross sectional view of the memory cell array 11 in FIG. 3A.

FIGS. 4B, 5B, 6B, 7B, 8B, 9B, 10B, 11B, 12B, 13B, 14B, 15B, 16B, 17B, 18B, 19B, and 20B are fragmentary cross sectional elevation views, taken along the B-B line of FIG. 2, and correspond to the fragmentary cross sectional view of the memory cell array 11 in FIG. 3B.

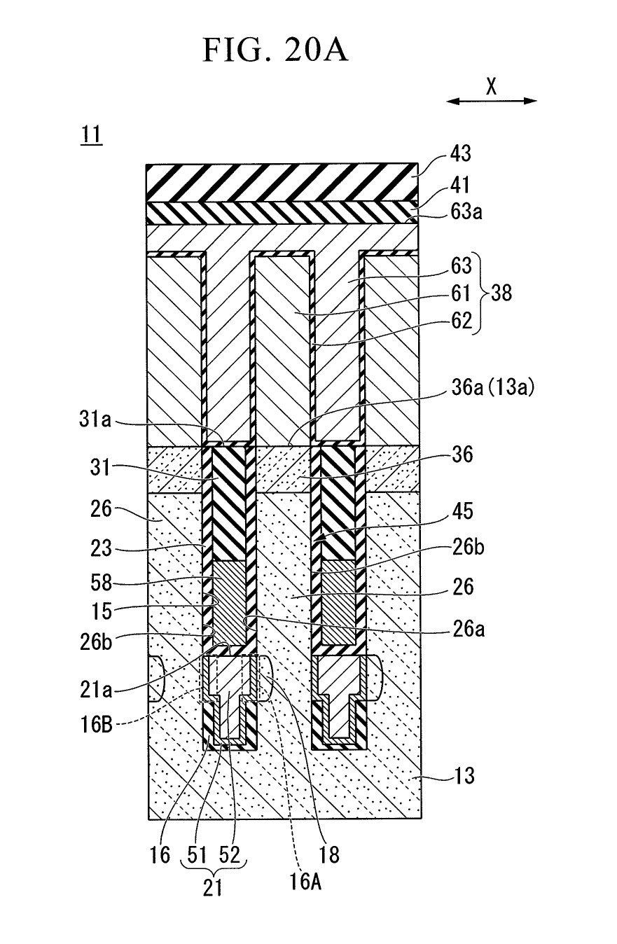

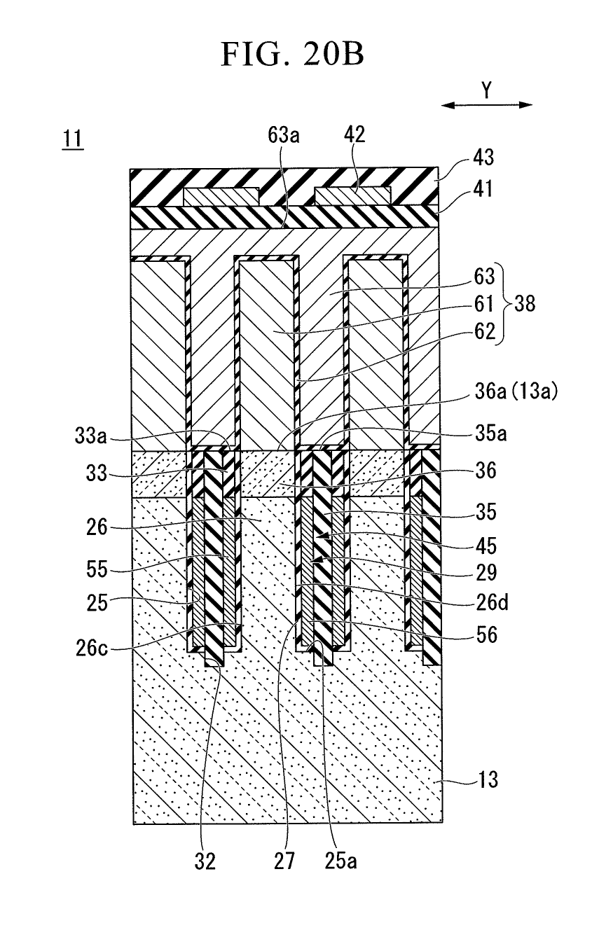

The same parts as those of the memory cell array 11 in FIGS. 1 through 3B are denoted by the same reference numerals in FIGS. 4A and 20B.

The method of forming the semiconductor device 10 (specifically, memory cell array 11) according to the first embodiment will be described with reference to FIGS. 4A through 20B.

As shown in FIGS. 4A and 4B, the silicon substrate (a silicon wafer, for example) including a low concentration of a p-type impurity (approximately 5E12-5E13 atoms/cm² as an ion implantation dosage) is prepared as the semiconductor substrate 13. The p-type well may be formed in advance by the ion implantation to include a predetermined concentration of the p-type impurity.

The isolation groove (not shown) is formed on the semiconductor substrate 13. The isolation insulating film (silicon oxide film (SiO₂ film)) is formed to be embedded in the isolation groove, thereby forming the isolation region (not shown). The memory cell region (active region) disposed inside the isolation region is defined.

A hard mask 66 is formed on the main surface 13a of the semiconductor substrate 13 by photo lithography and dry etching process. The hard mask 66 is formed of a silicon nitride film (Si₃N₄ film) and has a groove-shaped opening 66a extending in the Y-direction.

At this time, the opening 66a is formed to expose a portion of the main surface 13a of the semiconductor substrate 13a, which corresponds to a formation region of the first groove 15.

A silicon nitride film (Si₃N₄ film) to be processed into the hard mask 66 is formed by reduced-pressure CVD. The silicon nitride film (Si₃N₄ film) is formed with a thickness of, for example, 160 nm, but is not limited thereto.

When the p-type well is formed in the memory cell region, boron (B) may be implanted, as a p-type impurity, to the main surface 13a of the semiconductor substrate 13 by ion implantation after forming the isolation region and before forming the hard mask 66.

In this case, the Schottky barrier effect described above can be obtained by setting the dosage of the ion implantation a low value, for example, approximately 5E12-5E13 atoms/cm².

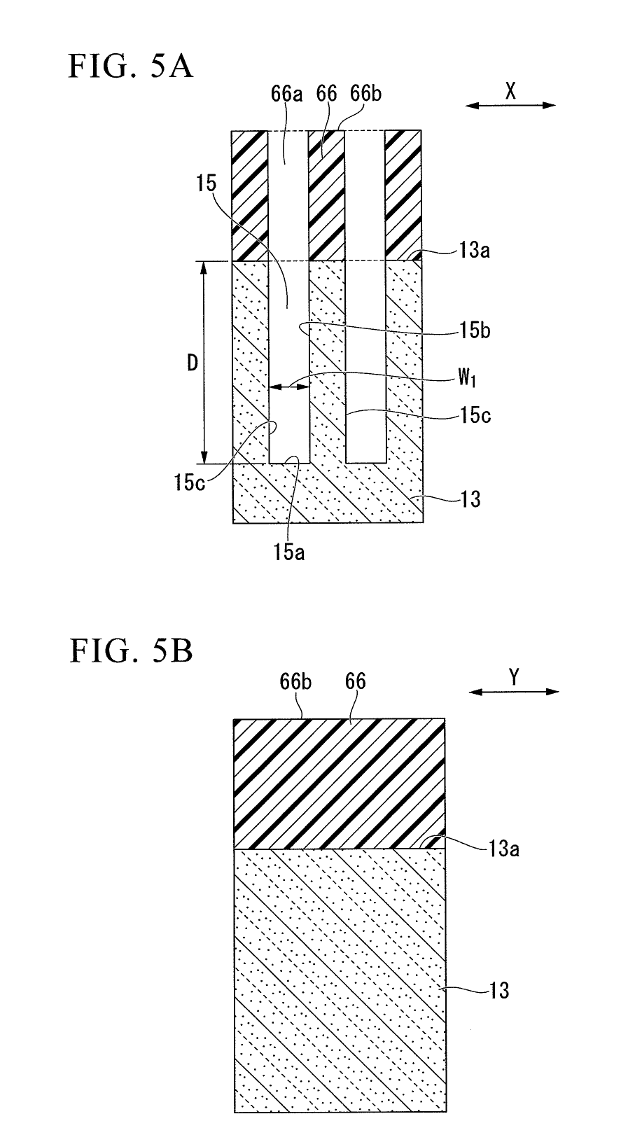

As shown in FIGS. 5A and 5B, the main surface 13a of the semiconductor substrate 13, which is located below the opening 66a is partially etched by anisotropic etching process (specifically, dry etching process) using the hard mask 66 as a mask, thereby forming the first groove 15. The first groove 15 extends in the Y-direction and is defined by the inside walls including the bottom surface 15a and the first and second side wall surfaces 15b and 15c.

A width W₁ of the first groove 15 may be 45 nm, but is not limited thereto. When the main surface 13a of the substrate 13 is regarded as a reference, a depth D of the first groove 15 may be 250 nm, but is not limited thereto.

RIE (Reactive Ion etching) by ICP (Inductively Coupled Plasma) is performed as the dry etching process.

In this case, sulfur fluoride with a flow rate of 90 sccm and chlorine (Cl₂) with a flow rate of 100 sccm may be used as etching gas, for example. As etching conditions other than the etching gas, source power may be 1000 W, high-frequency power may be 50 W to 200 W, and pressure inside a chamber may be 5 mTorr to 20 mTorr. However, the etching conditions are not limited thereto.

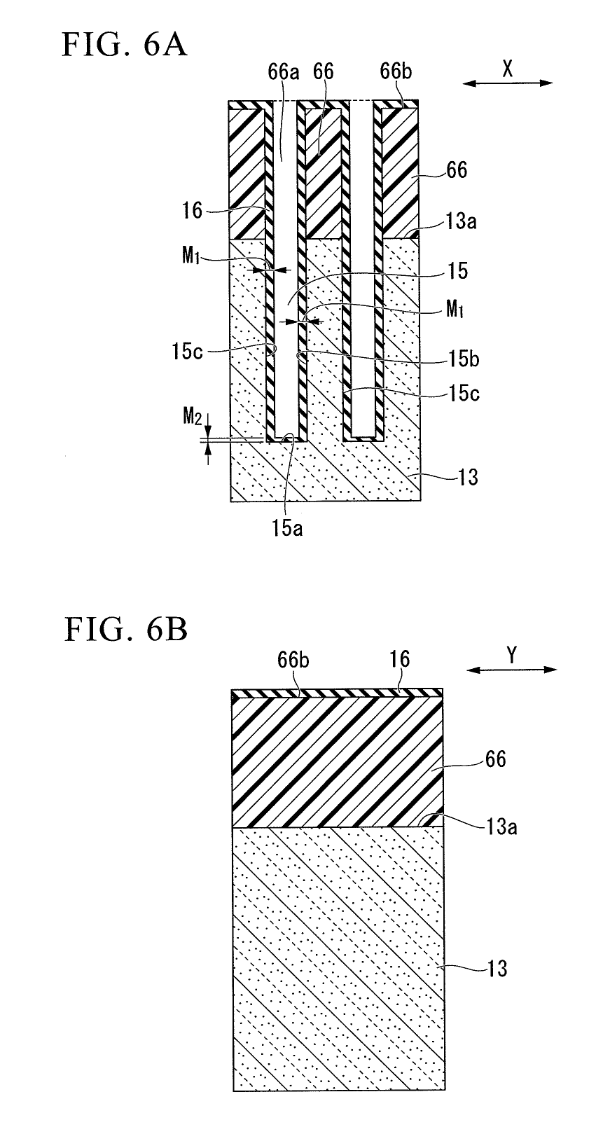

As shown in FIGS. 6A and 6B, the insulating film 16 is deposited to cover surfaces of the hard mask 66, which correspond to side surfaces of the opening 66a, the first and second side wall surfaces 15b and 15c of the first groove 15, and the bottom surface 15a of the first groove 15. At this time, the insulating film 16 is also deposited on a top surface 66b of the hard mask 66.

For example, a silicon oxide film (SiO₂ film) may be formed as the insulating film 16 by radical oxidation method in an atmosphere of 800° C. to 900° C.

At this time, by setting a thickness M₁ of the silicon oxide film (SiO₂ film) formed on the first and second side wall surfaces 15b and 15c 10 nm, the silicon oxide film (SiO₂ film) on the bottom surface 15a of the first groove 15 is formed thinner than M₁.

In this case, a thickness M₂ of the silicon oxide film (SiO₂ film) on the bottom surface 15a of the first groove 15 is approximately 6 nm. It is considered that this phenomenon is occurred because oxygen which is an oxidizing specie is diluted near the bottom surface 15a of the first groove 15 compared to above the bottom surface 15a.

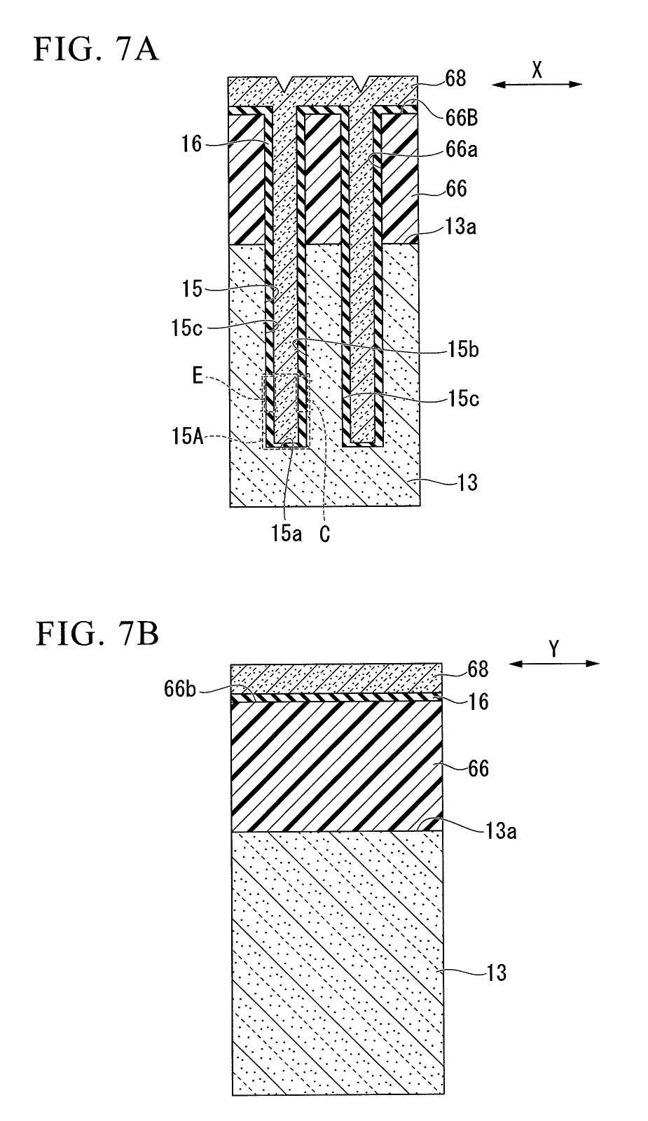

As shown in FIGS. 7A and 7B, a polysilicon film 68 is deposited by reduced-pressure CVD to fill the first groove 15 and the opening 66a on which the insulating film 16 is formed. At this time, the polysilicon film 68 is also deposited over a top surface 66b of the hard mask 66.

Of the polysilicon film 68 shown in FIG. 7A, a first portion formed in the bottom portion 15A of the first groove 15 functions as a mask in a process which will be described later. Specifically, the insulating film 16 which is disposed above the bottom portion 15A of the first groove 15 and on the first and second side wall surfaces 15b and 15c is recessed by etching process using the first portion of the polysilicon film 68 as the mask.

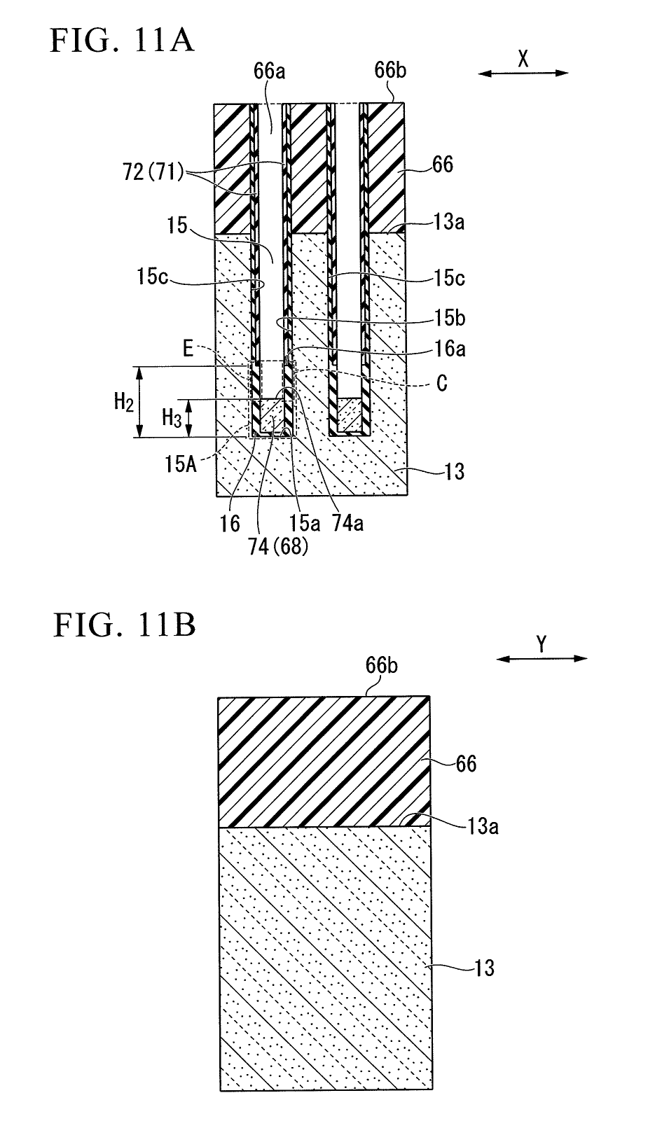

Of the polysilicon film 68 shown in FIG. 7A, a second portion below a region where the first opening 16A will be formed (refer to as an “opening formation region C” hereafter) and a third portion below a region where the second opening 16B will be formed (refer to as an “opening formation region E” hereafter) will be second etching masks 74 illustrated in FIG. 11A, which will be described later. That is, the polysilicon film 68 is processed to be the second etching masks 74.

The polysilicon film 68 illustrated in FIG. 7A will be removed eventually.

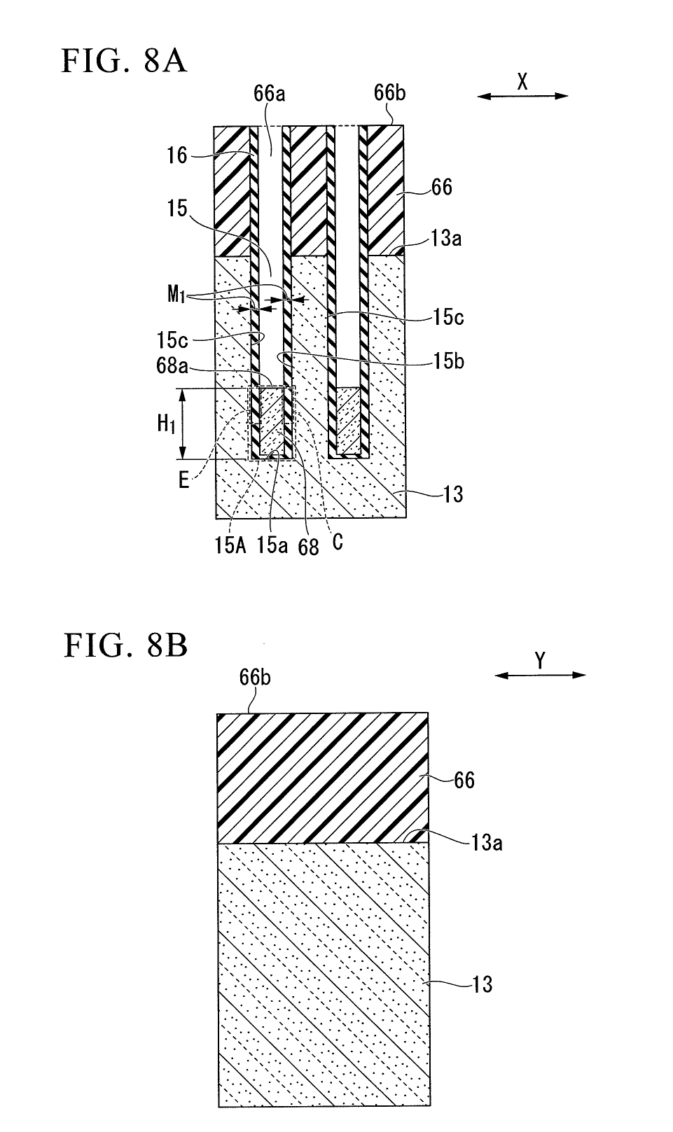

As shown in FIGS. 8A and 8B, an unnecessary portion of the polysilicon film 68 is etched back by dry-etching the structure illustrated FIGS. 7A and 7B from a top surface thereof. The unnecessary portion of the poly silicon film 68 is other than the polysilicon film 68 formed in the bottom portion 15A of the first groove 15. Thereby, the polysilicon film 68 remains only in the bottom portion 15A of the first groove 15.

At this time, the polysilicon film 68 is left so that a height H₁ of a top surface 68a of the polysilicon film 68 after the etch-back process is approximately 90 nm when the bottom surface 15a of the first groove 15 is regarded as a reference.

By the etch-back process, the insulating film 16 and the polysilicon film 68 laminated on the top surface 66b of the hard mask 66 are removed, and the insulating film 16 in the first groove 15 and the opening 66a remains.

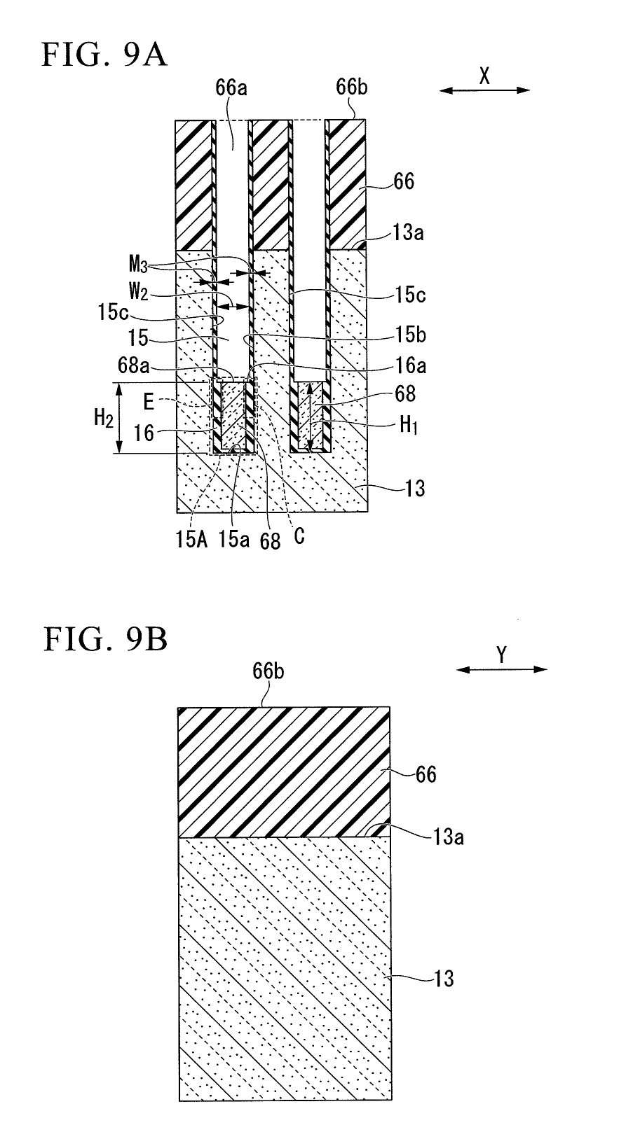

As shown in FIGS. 9A and 9B, the insulating film 16 above the opening formation regions C and E is wet-etched using the polysilicon film 68 remaining in the bottom portion 15A of the first groove 15 as a mask. Thereby, the insulating film 16 above the opening formation regions C and E is recessed.

For example, the insulating film 16 above the opening formation regions C and E is wet-etched using buffered hydrofluoric acid (mixture of hydrofluoric acid and ammonium fluoride) at 20° C. Thereby, the thickness M₃ of the insulating film 16 after the wet-etching process is approximately 5 nm.

At this time, as shown in FIG. 9A, the insulating film 16 in the bottom portion 15A of the first groove 15 is hardly etched since the insulating film 16 in the bottom portion 15A of the first groove 15 is protected by the polysilicon film 68. Therefore, the height H₁ from the bottom surface 15a of the first groove 15 to the top surface 68a of the polysilicon film 68 is substantially the same as a height H₂ from the bottom surface 15a of the first groove 15 to the top surface 16a of the insulating film 16.

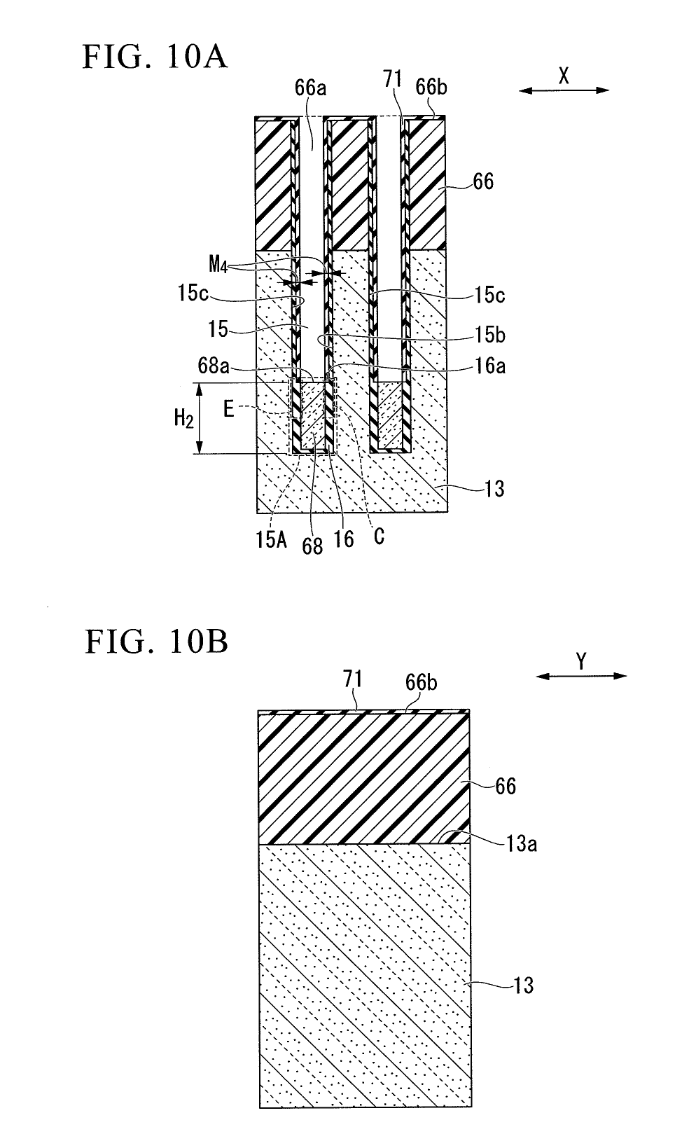

As shown in FIGS. 10A and 10B, a silicon nitride film 71 is formed by reduced-pressure CVD to cover an inside of the first groove 15, where the polysilicon film 68 and the insulating film 16 are formed, and the insulating film 16 formed in the opening 66a. The inside of the first groove 15 corresponds to side surfaces of the insulating film 16 formed on the first and second side surfaces 15b and 15c, the top surface 16a of the insulating film 16 formed in the bottom portion 15A, and the top surface 68a of the polysilicon film 68. At this time, the silicon nitride film 71 is also formed over the top surface 66b of the hard mask 66.

The silicon nitride film 71 will be processed into a first etching mask 72 formed in a process illustrated in FIGS. 11A and 11B which will be described later.

A thickness M₄ of the silicon nitride film 71 which is formed on the insulating film 16 on the first and second side wall surface 15b and 15c may be approximately 5 nm. However, the thickness M₄ is not limited thereto.

As shown in FIGS. 11A and 11B, the silicon nitride film 71 formed on the top surface 66b of the hard mask 66 and on the top surface 68a of the polysilicon film 68 is removed by etching back the silicon nitride film 71 illustrated in FIGS. 10A and 10B. Thereby, the top surface 66b of the hard mask 66 and the top surface 68a of the polysilicon film 68 are exposed and the first etching mask 72 covering the insulating film 16 formed above the opening formation regions C and E is formed as a side wall. The insulating film 16 formed above the opening formation regions C and E corresponds to the insulating film 16 thinned by wet-etching process in the process illustrated in FIGS. 9A and 9B.

The polysilicon film 68 illustrated in FIG. 10A is etched back to be embedded in the first groove 15 below the opening formation regions C and E, thereby forming the second etching mask 74.

By doing this, the insulating film 16 on the opening formation regions C and E are not covered by the first and second etching masks 72 and 74.

The etching back process is performed so as not to substantially form a step between a first portion of the insulating film 16 on the opening formation region C and the second etching mask 74 contacting the first portion of the insulating film 16. Also, the etching back process is performed so as not to substantially form a step between a second portion of the insulating film 16 on the opening formation region E and the second etching mask 74 contacting the second portion of the insulating film 16.

A height H₃ of a top surface of the second etching mask 74 may be approximately 60 nm when the bottom surface 15a of the first groove 15 is regarded as a reference. However, the height H₃ of the top surface of the second etching mask 74 is not limited thereto.

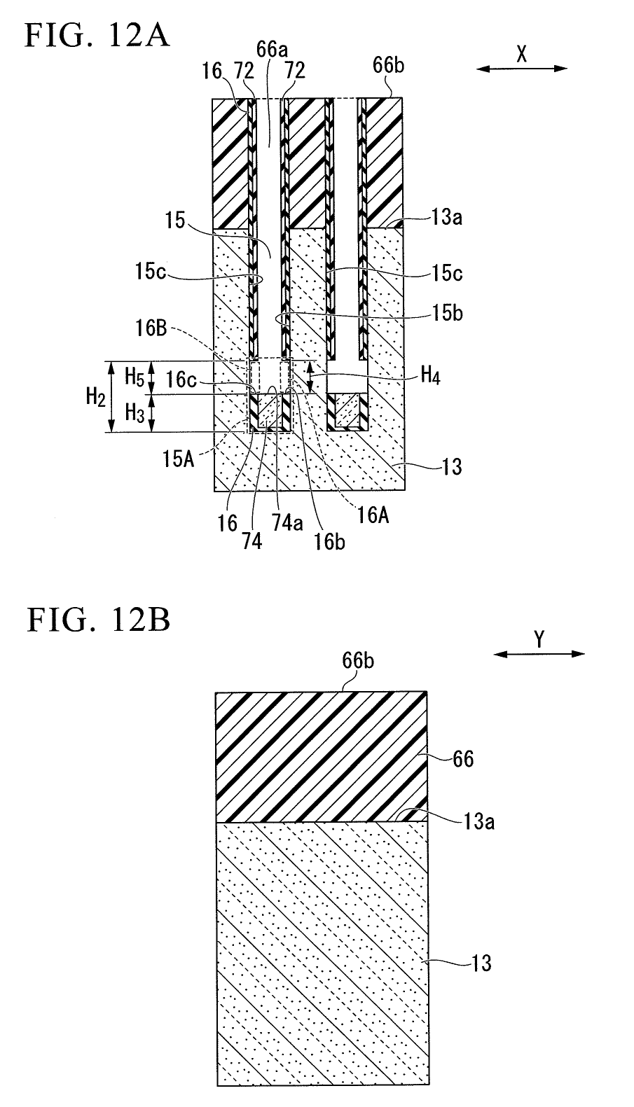

As shown in FIGS. 12A and 12B, the insulating film 16 in the bottom portion 15A of the first groove 15, which is not covered by the first and second etching masks 72 and 74, is selectively removed by wet-etching process. By doing this, the first and second openings 16A and 16B are formed in the same step. The first side wall surface 15b of the first groove 15, which is the surface of the semiconductor substrate 13, is shown through the first opening 16A. The second side wall surface 15c of the first groove 15, which is the surface of the semiconductor substrate 13, is shown through the second opening 16B. By doing this, the insulating film 16 having the first and second openings 16A and 16B is formed in the bottom portion 15A of the first groove 15.

The second opening 16B is formed to be opposed to the first opening 16A by the above described etching process. As described above, the first and second openings 16A and 16B are formed in the same step by selectively etching portions of the insulating film 16. The first side wall surface 15b of the first groove 15 is shown through the first opening 16A. The second side wall surface 15c of the first groove 15 is shown through the second opening 16B opposed to the first opening 16A. Since the first and second openings 16A and 16B are formed in the same step by selectively etching the insulating film 16, the process for forming the first and second openings 16A and 16B is easier than in the related art. In the related art, the photoresist mask covering the insulating film formed on one side wall surface of the pillar is necessary in order to form the opening only on the other side wall surface of the pillar. However, the photoresist mask is not necessary in the present embodiment. According to the present embodiment, the buried bit line 21 which is miniaturized can be formed in the first groove 15, which is formed in the semiconductor substrate 13, to be in contact with the lower impurity diffusion region 18.

As shown in FIG. 12A, a surface 16b of the insulating film 16 and a surface 16c of the insulating film 16 are substantially aligned with the top surface 74a of the second etching mask 74.

A height H₄ of the first opening 16A in the case where the surface 16b of the insulating film 16 is regarded as a reference is substantially the same as a height H₅ of the first opening 16B in the case where the surface 16c of the insulating film 16 is regarded as a reference.

The heights H₄ and H₅ may be, but is not limited to, approximately 30 nm.

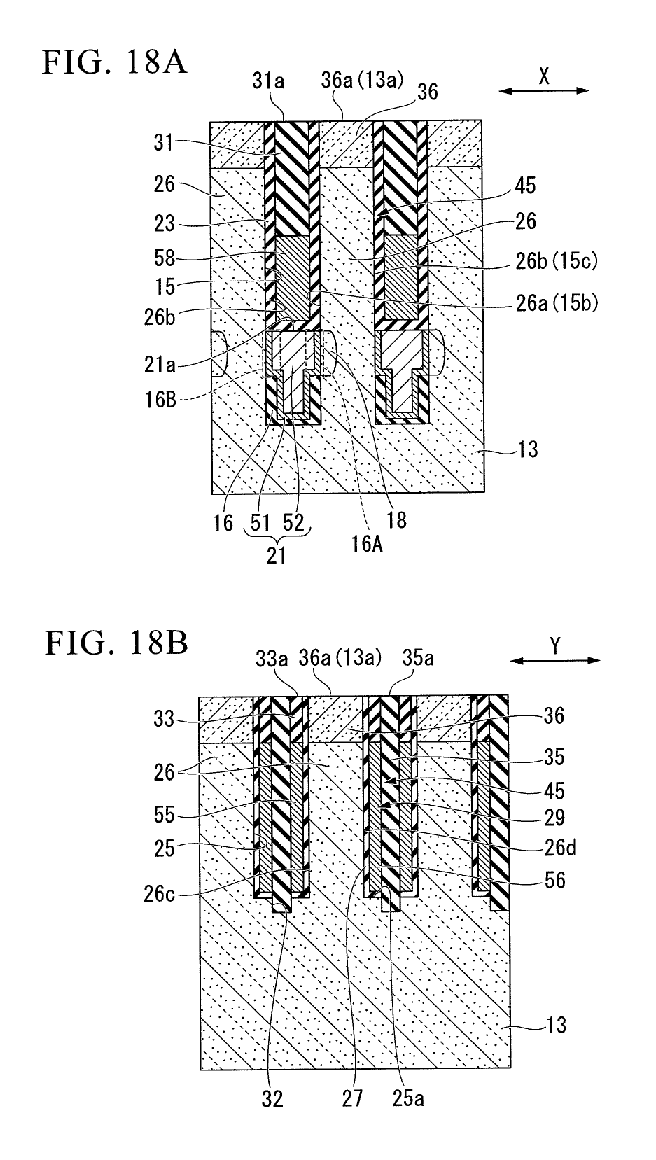

The first side wall surface 15b shown through the first opening 16A corresponds to the side wall surface 26a of the pillar 26 illustrated in FIG. 18A when the pillar 26 is formed in a process shown in FIGS. 18A and 18B, which will be described later.

The first side wall surface 15c shown through the second opening 16B corresponds to the side wall surface 26b of the pillar 26 illustrated in FIG. 18A when the pillar 26 is formed in the process shown in FIGS. 18A and 18B, which will be described later.

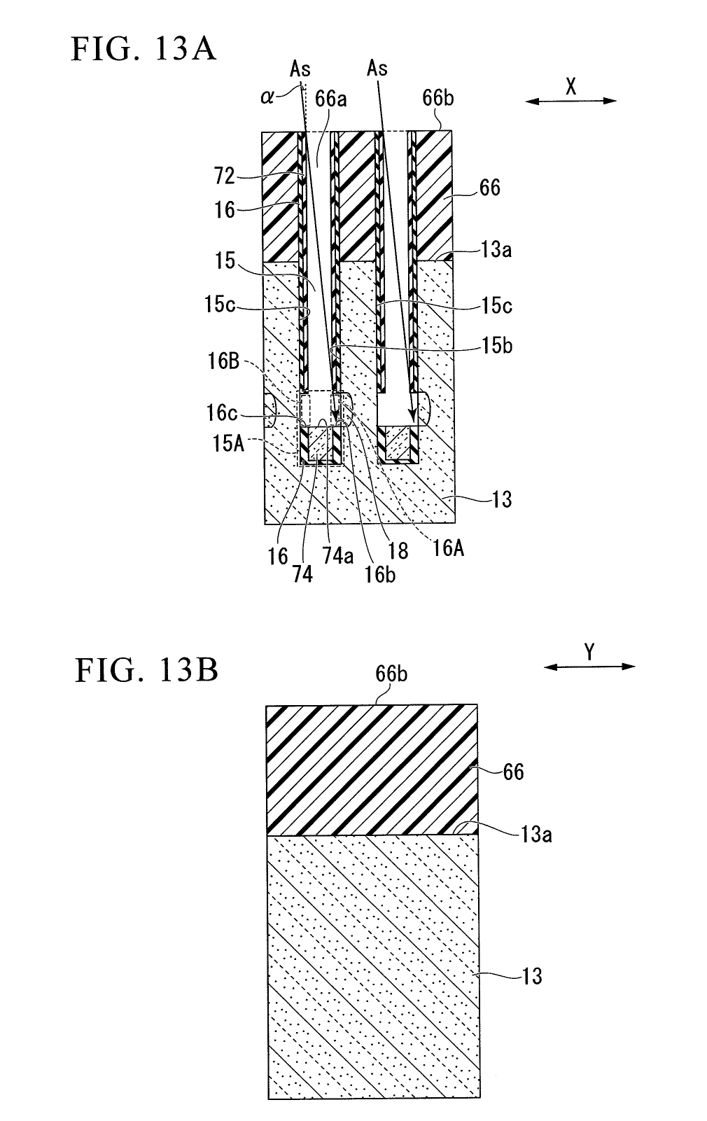

As shown in FIGS. 13A and 13B, arsenic (As) ion which is an n-type impurity is implanted to the first side wall surface 15b, which is shown through the first opening 16A illustrated in FIG. 12A, through the first groove 15 and the first opening 16A with a predetermined implantation angle α by oblique ion implantation.

At this time, the first and second etching masks 72 and 74 are used as masks while the oblique ion implantation is performed. Thereby, the arsenic (As) ion is selectively implanted to the first side wall surface 15b which is shown through the first opening 16A.

For example, arsenic (As) ion is implanted to the first side wall surface 15b which is shown through the first opening 16A by the oblique ion implantation using an ion implantation apparatus (not shown) in a condition where an implantation energy is 5 keV-10 keV, a dosage is 5E14-5E15 atoms/cm², and an implantation angle α is more than 4° and less than 5°.

When the implantation angle α is less than 4°, a ratio of arsenic (As) ion implanted to a surface of the second etching mask 74 is increased, thereby lowering an implantation efficiency of arsenic (As) ion to the first side wall surface 15b shown through the first opening 16A. The second etching mask 74 is a mask formed by polysilicon film and is formed on the bottom portion 15A of the first groove 15.

When the implantation angle α is more than 5°, arsenic (As) ion can not be implanted to a lower part of the first side wall surface 15b shown through the first opening 16A. That is, arsenic (As) ion cannot be implanted to the entire first side wall surface 15b shown through the first opening 16A.

The implantation angle α may be appropriately set in consideration of the depth from the top surface 66b of the hard mask 66 to the opening formation regions C and E, the width of the first groove 15 or the like.

The semiconductor substrate 13 is heated so that arsenic (As) ions are diffused into the semiconductor substrate 13, thereby forming the lower impurity diffusion region 18 shown through the first opening 16A. The lower impurity diffusion region 18 is an n-type impurity diffusion region in this case.

For example, the semiconductor substrate 13 is rapidly heated in a nitrogen atmosphere at around 900° C. using a lamp annealing apparatus (not shown). Arsenic (As) ions are diffused into the semiconductor substrate 13 by heating, thereby forming the lower impurity diffusion region 18 shown through the first opening 16A.

Since the lower impurity diffusion region 18 is formed in the semiconductor substrate 13 shown through the first opening 16A by oblique ion implantation, it can be prevented to form an impurity diffusion region including arsenic (As) ion through the second opening 16B.

A part of the semiconductor substrate 13 corresponding to the second side wall surface 15c shown through the second opening 16B is maintained to have the p-type conductivity.

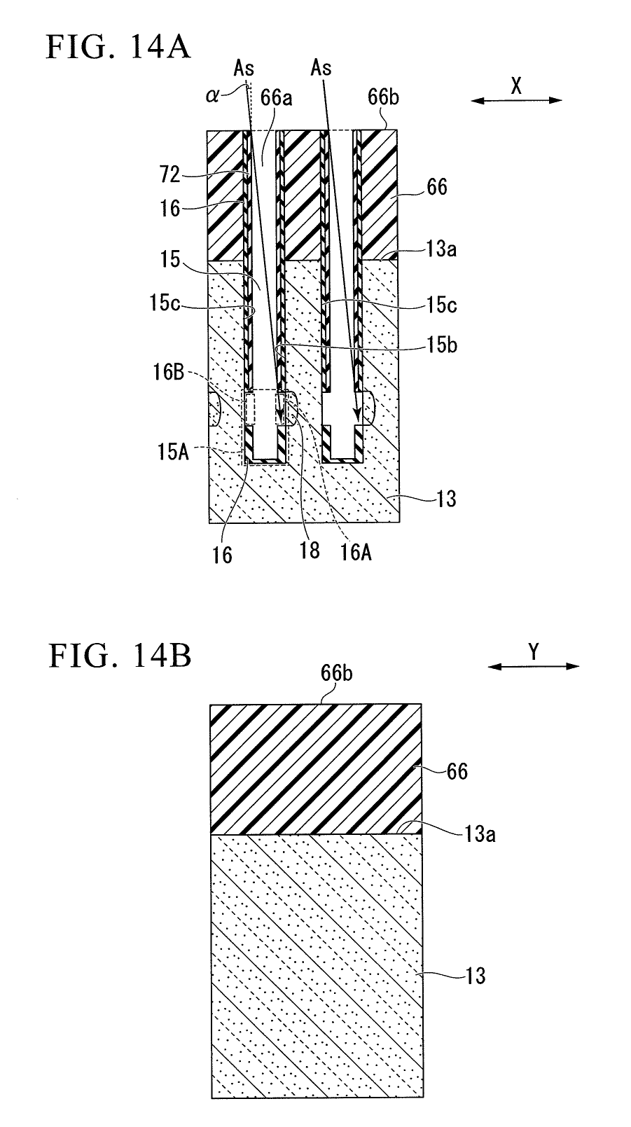

As shown in FIGS. 14A and 14B, the second etching mask 74 which is the mask formed by the polysilicon film illustrated in FIG. 13A is selectively removed by etching-back process.

Since the insulating film 16 is the silicon oxide film and the first etching mask 72 is the silicon nitride film, only the second etching mask 74 which is the polysilicon film is selectively removed. As shown in FIG. 14A, the insulating film 16 and the first etching mask 72 remain after etching-back process.

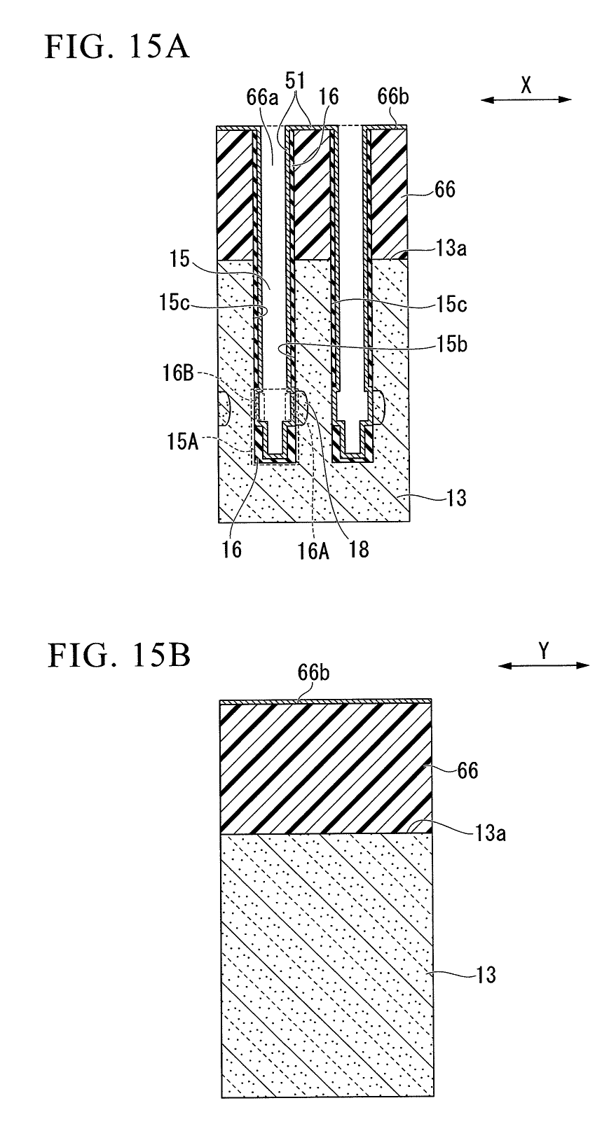

As shown in FIGS. 15A and 15B, the first etching mask 72 illustrated in FIG. 14A is removed by wet etching process using etchant selectively etching the first etching mask 72 which is a mask formed by the silicon nitride film.

For example, the first etching mask 72 is selectively removed by soaking the structure illustrated in FIGS. 14A and 14B in hot phosphoric acid (H₃PO₄) heated at 130° C. to 160° C.

The first metal film 51 is deposited to cover an inside surface of the first groove 15 on which the insulating film 16 is formed and the first and second openings 16A and 16B. The first metal film 51 functions as a barrier film.

For example, a titanium (Ti) film with a thickness of, for example, 10 nm and a titanium nitride (TiN) film with a thickness of, for example, 10 nm are sequentially deposited by CVD to cover the inside surface of the first groove 15 on which the insulating film 16 is formed and the first and second openings 16A and 16B. Thereby, the first metal film 51 including the titanium film and the titanium nitride film is formed.

The first metal film 51 is in contact with the lower impurity diffusion region 18 having the n-type conductivity through the first opening 16A. Also, the first metal film 51 is in contact with second side wall surface 15c, which is the semiconductor substrate having the p-type conductivity, through the second opening 16B.

The first metal film 51 formed on the bottom portion 15A on the first groove 15 is processed into the buried bit line 21. The first metal film 51 is also deposited on the top surface 66b of the hard mask 66.

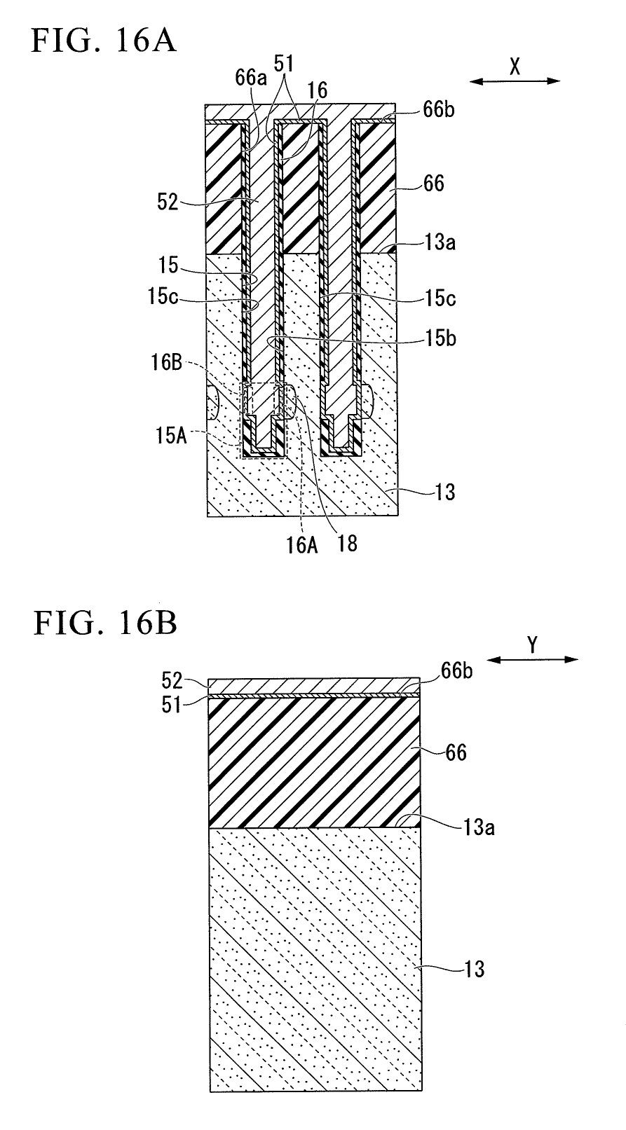

As shown in FIGS. 16A and 16B, the second metal film 52 is deposited by CVD on a surface of the first metal film 51 with which the structure illustrated in FIGS. 15A and 15B is provided. The second metal film 52 is lower in resistivity than the first metal film 51. The second metal film 52 fills the first groove 15 while the first metal film 51 is interposed between the second metal film 52 and the surfaces of the first groove 15. The second metal film 52 may include, but is not limited to, a tungsten (W) film. The second metal film 52 may be a tungsten (W) film.

The second metal film 52 in the bottom portion 15A of the first groove 15 will be processed into the buried bit line 21.

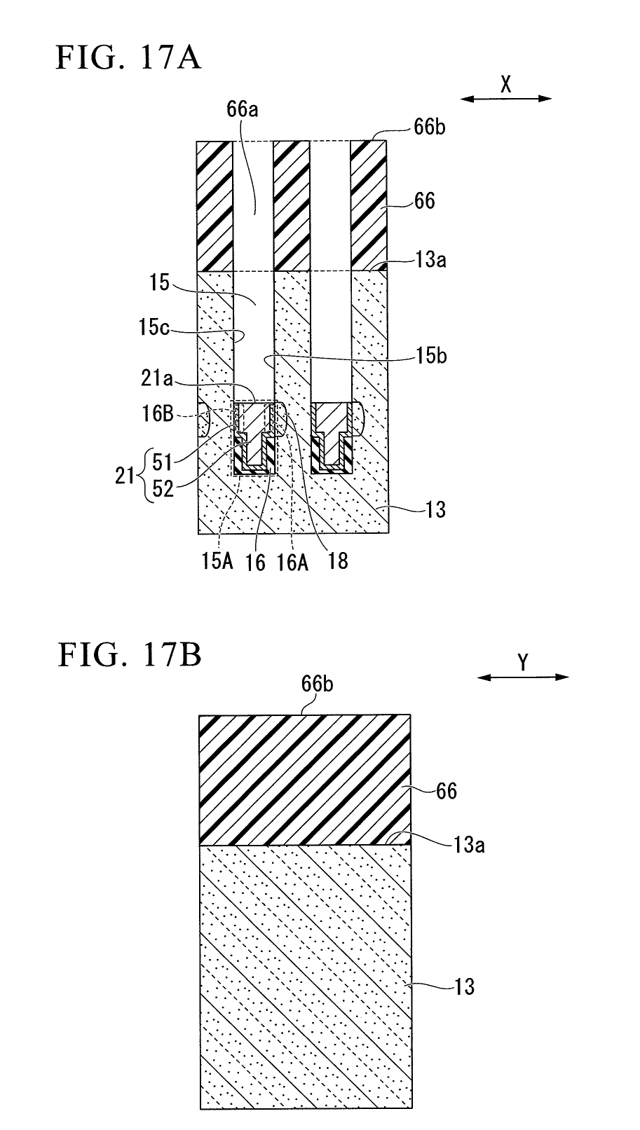

As shown in FIGS. 17A and 17B, the first and second metal films 51 and 52 with which the structure illustrated in FIGS. 16A and 16B is provided are etched-back to remain in the bottom portion 15A of the first groove 15.

The buried bit line 21 including the first and second metal films 51 and 52 and extending in the Y-direction is formed in the bottom portion 15A of the first groove 15.

Etching back the first and second metal films 51 and 52 is performed so as not to expose the lower impurity diffusion region 18 which is formed on the first side wall surface 15b and is covered by the first metal film 51.

As shown in FIGS. 18A and 18B, the insulating film 23 is formed. The insulating film 23 covers the top surface 21a of the buried bit line 21 and the first and the second side wall surfaces 15b and 15c of the first groove 15, which are positioned above the buried bit line 21. The first and the second side wall surfaces 15b and 15c of the first groove 15, which are positioned above the buried bit line 21, correspond to the side wall surfaces 26a and 26b of the plurality of pillars 26. The insulating film 23 may include, but is not limited to, a SiON film. The insulating film 23 may be the SiON film.

A silicon oxide film (SiO₂ film, not shown) is applied by SOG (Spin On Glass). The silicon oxide film fills the first groove 15 in which the insulating film 23 is formed. Then, the applied silicon oxide film (not shown) is etched-back and remains only in the first groove 15 which corresponds to a formation region of the connector 58.

A silicon oxide film (SiO₂ film) is deposited by HDP (High Density Plasma) to fill the first groove 15 in which the insulating film 23 and the applied silicon oxide film (not shown), thereby forming the first buried insulating film 31.

The plurality of second grooves 25 are formed by selectively etching the main surface 13a of the semiconductor substrate 13. The plurality of second grooves 25 cross the first grooves 15 and extend in the X-direction. Each second groove 25 is defined by an inside surface including side walls corresponding the side wall surfaces 26c and 26d of the pillar 26.

The second groove 25 is formed by the same processes as the first groove 15 described above, specifically the processes shown in FIGS. 4A through 5B. The second groove 25 is formed so that the applied silicon oxide film (not shown) formed by SOG is completely exposed.

The plurality of pillars 26 are formed by processing the semiconductor substrate 13. Each pillar 26 is surrounded by the first and second grooves 15 and 25. Each of the plurality of pillars 26 has a pillar shape.

The side wall surface 26a of the pillar 26 corresponds to the first side wall surface 15b of the first groove 15. The side wall surface 26b of the pillar 26 corresponds to the second side wall surface 15c of the first groove 15. The side wall surfaces 26a and 26b are opposed to each other in the X-direction.

The side wall surfaces 26c and 26d correspond to side wall surfaces of the second groove 25. The side wall surfaces 26c and 26d are opposed to each other in the X-direction.

The applied silicon oxide film (not shown) remaining in the first groove 15 is selectively removed by wet etching process. Then, the gate insulting film 27 is formed to cover an inside surface of the second groove 25. The inside surface of the second groove 25 corresponds to the bottom surface 25a of the second groove 25 and the side wall surfaces 26c and 26d of the plurality of the pillars 26.

As the gate insulating film 27, a single silicon oxide film (SiO₂ film), a nitrided silicon oxide film (SiON film), a lamination that is formed by laminating a silicon nitride film (SiN film) or a high dielectric film (High-k film) on the silicon oxide film (SiO₂ film), a single high dielectric film, or the like may be used, for example. However, the gate insulating film 27 is not limited thereto.

A conductive film (not shown) which will be processed into the word line 29 is deposited by CVD to fill the first and second grooves 15 and 25 corresponding to the formation region of the connector 58.

For example, the conductive film including a titanium (Ti) film, a titanium nitride (TiN) film, and a tungsten (W) film is formed by sequentially laminating the titanium (Ti) film, the titanium nitride (TiN) film, and the tungsten (W) film.

By doing this, the plurality of connectors 58 formed of the conductive film described above are formed in the first groove 15. At this time, the electrode end connector 57 (not shown in FIGS. 18A and 18B, refer to FIGS. 1 and 2) is formed in the same process.

The conductive film formed in the second groove 25 is etched-back so that the conductive film remaining in the second groove 25 has a predetermined thickness. The conductive film remaining in the second groove 25 will be processed into the gate electrodes 55 and 56.

The separation groove 32 is formed in the second groove 25. The separation groove 32 is smaller in width than the second groove 25. The separation groove 32 extends in the X-direction. The separation groove 32 divides the conductive film remaining in the second groove 25 into two parts.

By doing this, the gate electrode 55 is formed on the side wall surface 26c of each of the plurality of pillars 26 while the gate insulating film 27 is interposed between the gate electrode 55 and the side wall surface 26c. Also, the gate electrode 56 is formed on the side wall surface 26d of each of the plurality of pillars 26 while the gate insulating film 27 is interposed between the gate electrode 55 and the side wall surface 26c.

That is, the word line 29 including the electrode end connector 63, the connector 65, and the gate electrodes 55 and 56 extending in the X-direction is formed at this stage.

The liner film 33 is formed on the gate electrodes 55 and 56 so as to contact the gate insulating film 27. The liner film 33 may include, but is not limited to a SiON film. The liner film 33 may be the SiON film.

The second buried insulating film 35 fills the separation groove 32. As the second buried insulating film 35, an applied silicon oxide film (SiO₂ film) formed by SOG may be used. However, the second buried insulating film 35 is not limited thereto.

The hard mask 66 which is illustrated in FIGS. 17A and 17B and was used in the formation of the first and second groove 15 and 25 is removed. By doing this, the top surfaces of the plurality of pillars 26, which is the main surface 13a of the semiconductor substrate 13 are shown.

Arsenic (As) ion as an n-type impurity is introduced to the top surfaces of the plurality of pillars 26 (the main surface 13a of the semiconductor substrate 13). Arsenic ions are diffused by heating to form the upper impurity diffusion region 36 in a top portion of each of the plurality of pillars 26.

As described above, the vertical MOS transistor 45 including the lower impurity diffusion region 18, the upper impurity diffusion region 36, the gate insulating film 27, and the gate electrodes 55 and 56 is formed in each of the plurality of pillars 26.

The top surface 36a of the upper impurity diffusion region 36 is aligned with the main surface 13a of the semiconductor substrate 13.

As shown in FIGS. 18A and 18B, of the insulating films which includes the insulating film 23, the first and second buried insulating film 31 and 35, and the liner film 33, a portion protruding from the top surface 36a of the upper impurity diffusion region 36 is removed. Thereby, a structure whose top surface is planarized is formed as shown in FIGS. 18A and 18B.

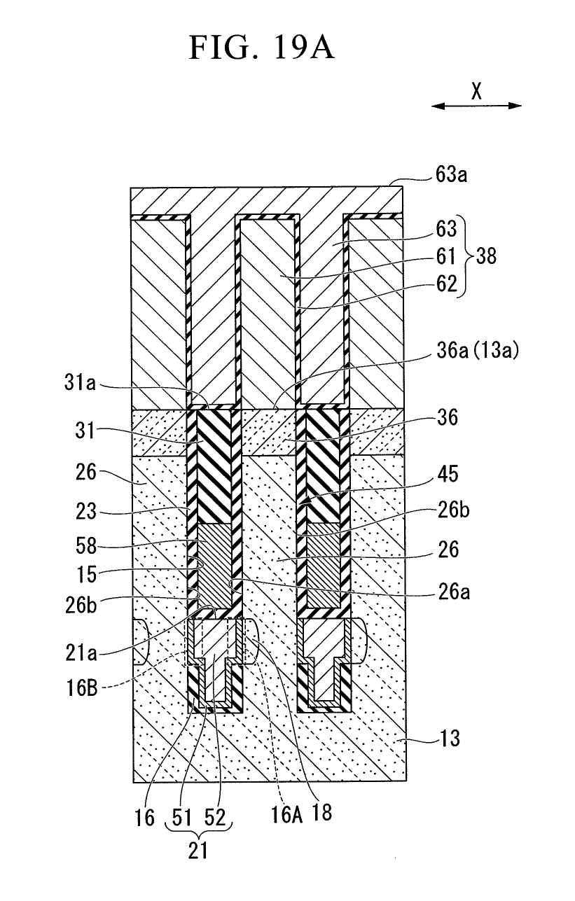

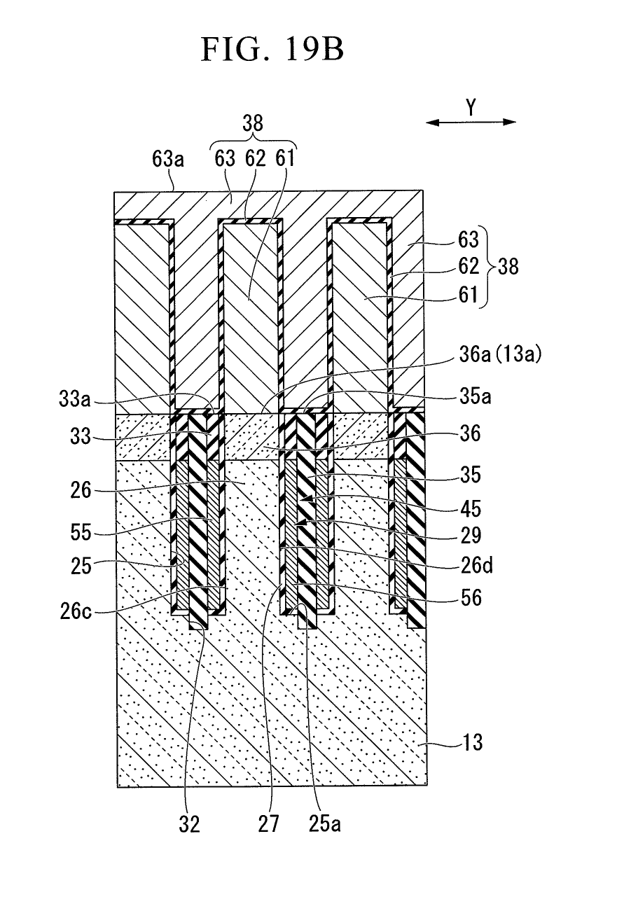

As shown in FIGS. 19A and 19B, the lower electrode 61, the capacitor insulating film 62, and the upper electrode 63 are sequentially formed on the structure illustrated in FIGS. 18A and 18B to form the capacitor 38 by the known method. The lower electrode 61 contacts the top surface 36a of the upper impurity diffusion region 36. The capacitor insulating film 62 covers a surface of the lower electrode 61. The capacitor insulating film 62 is common to the plurality of lower electrodes 61. The upper electrode 63 covers a surface of the capacitor insulating film 62 and fills the gap between the plurality of lower electrodes 61 on which the capacitor insulating film 62 is formed. The upper electrode 63 is common to the plurality of lower electrodes 61. The capacitor 38 includes the lower electrode 61, the capacitor insulating film 62, and the upper electrode 63.

The upper electrode 63 is polished so that a top surface of the upper electrode 63a is planarized.

As the lower electrode 61, the lamination formed by sequentially laminating a titanium (Ti) film and a titanium nitride (TiN) film may be used, for example. In this case, the titanium (Ti) film may be formed with a thickness of, for example, 10 nm. However, the lower electrode 61 is not limited thereto.

As the capacitor insulating film 62, the lamination formed by laminating an aluminum oxide film (Al₂O₃ film) and a zirconium oxide film (ZrO₂ film) in this order may be used, for example. However, the capacitor insulating film 62 is not limited thereto.

As the upper electrode 63, the metal film such as a ruthenium (Ru) film, a tungsten (W) film, a titanium nitride (TiN) film, a lamination of the metal film and a polysilicon film or the like may be used. However, the upper electrode 63 is not limited thereto.

As shown in FIGS. 20A and 20B, the silicon oxide film (SiO₂ film) is formed to cover the top surface 63a of the upper electrode 63, thereby forming the interlayer insulating film 41.

The wiring 42 is formed on the interlayer insulating film 41 by the known method. The wiring 42 is electrically connected to the upper electrode 63.

The silicon oxide film (SiO₂ film) is deposited on the interlayer insulating film 41 to cover the wiring 42, thereby forming the interlayer insulating film 41, thereby forming the interlayer insulating film 43.

As described above, the semiconductor device 10 according to the present embodiment (the memory cell array 11) is formed.

According to the first embodiment, the method of forming the semiconductor device 10 may include, but is not limited to, the following processes. The semiconductor substrate 13 including the low concentration of the p-type impurity is prepared. The first groove 15 extending in the Y-direction is formed by partially etching the main surface 13a of the semiconductor substrate 13. The first groove 15 is defined by the inside surfaces including the bottom surface 15a and the first and second side wall surfaces 15b and 15c. The insulating film 16 is formed to cover the inside surfaces of the first groove 15. The first and second openings 16A and 16B are formed at the portions of the insulating film 16 deposited in the bottom portion 15A of the first groove 15. The first side wall surface 15b is shown through the first opening 16A. The second side wall surface 15c is shown through the second opening 16B. The lower impurity diffusion region 18 including the high concentration of the n-type impurity is formed by oblique ion implantation. Specifically, the lower impurity diffusion region 18 is formed by implanting the n-type impurity to the first side wall surface 15b, which is shown through the first opening 16A, through the first groove 15 and the first opening 16A. The buried bit line 21 is formed by embedding the first and second metal films 51 and 52 in the bottom portion 15A of the first groove 15, on which the insulating film 16 is formed, and the first and second openings 16A and 16B. Although it is necessary that the photoresist film is formed in order to form only the first opening 16A by etching process in the related art, the photoresist film is not necessary in the present embodiment. Also, the n-type impurity can be selectively implanted only to the first side wall surface 15b, which is shown through the first opening 16A while the first and second openings 16A and 16B are formed.

By doing this, the buried bit line 21 with a microfine shape can be formed in the bottom portion of 15A of the first groove 15. The buried bit line 21 which can be applied to the semiconductor device 10 which is miniaturized can be formed.

By forming the buried bit line 21 using the metal film, the resistivity of the buried bit line 21 can be reduced. By doing this, a high-performance semiconductor device can be formed.

As the first metal film 51, a metal film other than the titanium film can be used. In this case, ohmic contact between the first metal film 51 and the lower impurity diffusion region 18 can be formed by adjusting the n-type impurity concentration of the lower impurity diffusion region 18 in accordance with a work function of the metal film. Also, a connection between the first metal film 51 and the lower impurity diffusion region 18 with the Schottky bather can be formed by adjusting the p-type impurity concentration of the semiconductor substrate 13 shown through the second opening 16B.

According to the method for forming the semiconductor device 10 of the first embodiment, the lower electrode 61 is directly connected to the upper impurity diffusion region 36, but is not limited thereto. The silicide layer (not shown) may be formed on the upper impurity diffusion region 36. That is, the silicide layer may be formed between the capacitor 38 and the upper impurity diffusion region 36.

By forming the silicide layer (not shown) between the capacitor 38 and the upper impurity diffusion region 36, the contact resistance between the capacitor 38 and the upper impurity diffusion region 36 can be reduced.

The silicide layer may include, but is not limited to, a titanium silicide (TiSi₂) film. The silicide layer may be the titanium silicide (TiSi₂) film. The titanium silicide film has a low resistance among silicide layers. Also, even when a natural oxide film (silicon oxide film (SiO₂ film)) is formed on the top surface 36a of the upper impurity diffusion region 36, a stable solid state reaction between the silicon oxide film and the titanium silicide film (titanium reduces the silicon oxide film) is progressed.

In this case, the TiSi₂ film is formed by depositing the titanium film on the top surface 36a of the upper impurity diffusion region 36 by CVD.

Also, instead of providing with the silicide layer (not shown), the interlayer insulating film (not shown) may be formed on the structure illustrated in FIGS. 18A and 18B, and then the contact plug (not shown) penetrating the interlayer insulating film and contacting the top surface 36a of the upper impurity diffusion region 36 may be formed in order to connect the upper impurity diffusion region 36 and the lower electrode 61 via the contact plug. A material of the contact plug may be, but is not limited to, polysilicon or tungsten (W).

### Second Embodiment

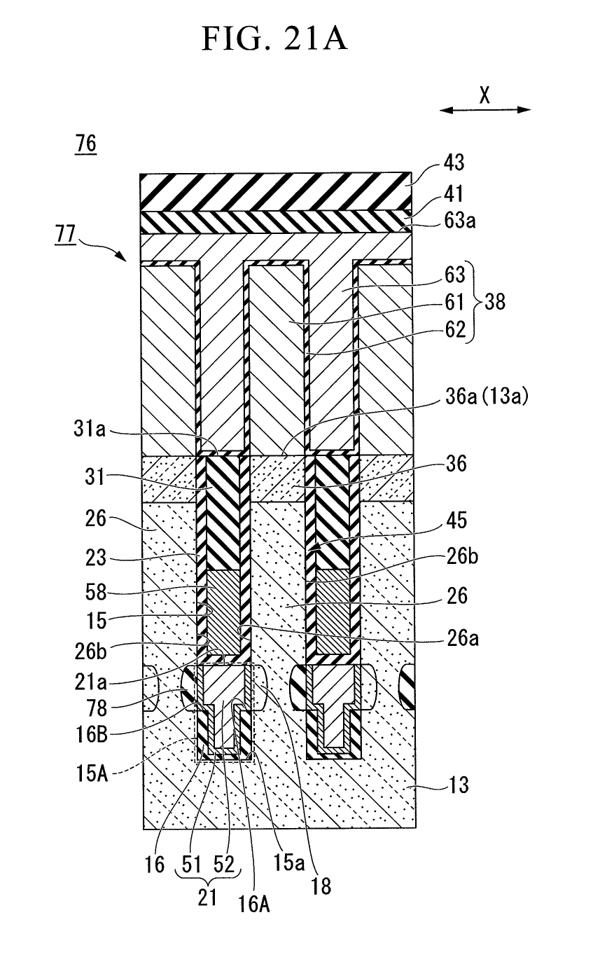

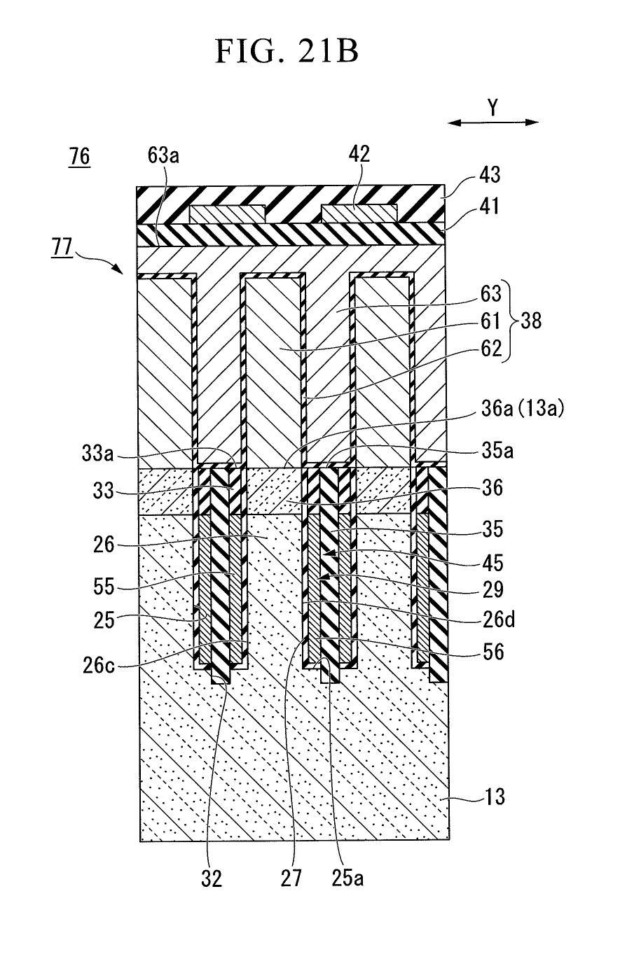

FIG. 21A is a fragmentary cross sectional elevation view, taken along the A-A line of FIG. 2, illustrating the memory cell array of a semiconductor device in accordance with another embodiment of the present invention. FIG. 21A corresponds to the fragmentary cross sectional view of the memory cell array 11 in FIG. 3A in the first embodiment. FIG. 21B is a fragmentary cross sectional elevation view, taken along the B-B line of FIG. 2, illustrating the memory cell array of the semiconductor device in accordance with another embodiment of the present invention. FIG. 21B corresponds to the fragmentary cross sectional view of the memory cell array 11 in FIG. 3B in the first embodiment. The same parts as those of the memory cell array 11 in FIGS. 3A and 3B are denoted by the same reference numerals in FIGS. 21A and 21B.

Although only a memory cell array 77 (memory cell region) with which a semiconductor device 76 according to the second embodiment is provided is shown, a peripheral circuit region (not shown) provided with a peripheral circuit transistor and the like is formed in the semiconductor device 76.

As shown in FIGS. 21A and 21B, the memory cell array 77 of the semiconductor device 76 according to the second embodiment has substantially the same structure as the memory cell array 11 of the semiconductor device 10 according to the first embodiment except for providing a silicon oxide 78 with the memory cell array 77.

The silicon oxide 78 has insulating properties and is formed on the side wall surface 26b of the pillar 26, which is shown through the second opening 16B. The silicon oxide 78 is formed by reacting oxygen (O) ion implanted by oblique ion implantation and silicon (Si) in the semiconductor substrate 13.

The first metal film 51 included in the buried bit line 21 is in contact with the silicon oxide 78 through second opening 16B.

According to the second embodiment, the buried bit line 21 including the first and second metal films 51 and 52 is in contact with the lower impurity diffusion region 18 with high impurity concentration through the first opening 16A and the silicon oxide 78 with insulating property through the second opening 16B.

According to the semiconductor device 76 of the second embodiment, the silicon oxide 78 which has the insulating property is formed on the side wall surface 26b of the pillar 26, which is shown through the second opening 16B. Since the silicon oxide 78 is in contact with the buried bit line 21 including the first and second metal films 51 and 52, an electrical separation between the buried bit line 21 and the semiconductor substrate 13 (including pillar 26) can be secured more than an electrical separation using the rectification property of the Schottky barrier. Also, small leak current can be suppressed by providing the silicon oxide 78. A high-performance memory cell array 77 can be achieved.

The semiconductor device 76 according to the second embodiment can provide the same effect as the semiconductor device 10 according to the first embodiment.

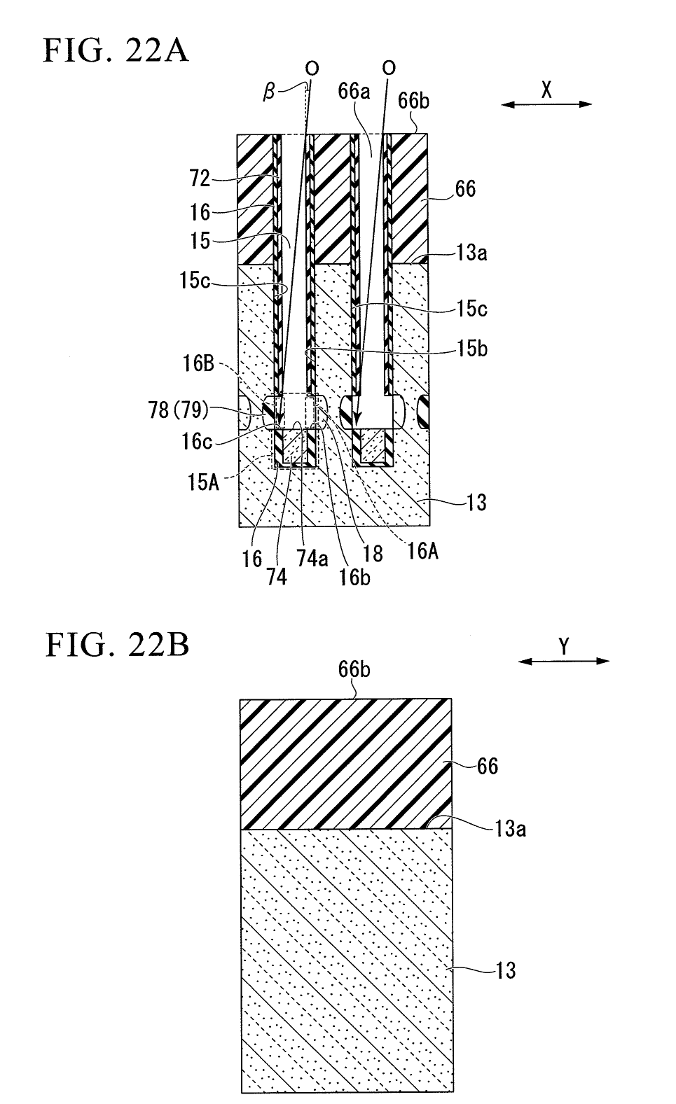

FIG. 22A is a fragmentary cross sectional elevation view, taken along the A-A line of FIG. 2, illustrating the memory cell array in a step involved in a method of forming the semiconductor device in accordance with another embodiment of the present invention. FIG. 22B is a fragmentary cross sectional elevation view, taken along the B-B line of FIG. 2, illustrating the memory cell array in a step, subsequent to the step of FIG. 19B, involved in the method of forming the semiconductor device of FIG. 1 in accordance with one embodiment of the present invention. The same parts as those of the memory cell array 11 in FIGS. 14A and 14B are denoted by the same reference numerals in FIGS. 22A and 22B.

A method of forming the semiconductor device 76 (memory cell array 77) according to the second embodiment will be described with reference to FIGS. 22A and 22B.

A structure illustrated in FIGS. 14A and 14B is formed by performing the same processes illustrated in FIGS. 4A through 14B, which are described in the first embodiment.

As shown in FIGS. 22A and 22B, an oxygen introducing region 79 is formed by oblique ion implantation. Specifically, the oxygen introducing region 79 is formed by ion-implanting oxygen (O) ions into the second side wall surface 15c of the first groove 15, which is shown through the second opening 16B, through the first groove 15 and the second opening 16B.

For example, the oxygen introducing region 79 is formed by implanting oxygen (O) ions to the second side wall surface 15c, which is shown through the second opening 16B by oblique ion implantation using an ion implantation apparatus (not shown) at a condition where an implantation energy is 3 keV-36 keV, a dosage is 1E16-1E18 atoms/cm², and an implantation angle β is more than 4° and less than 5°.

When the implantation angle β is less than 4°, a ratio of oxygen (O) ions implanted to a surface of the second etching mask 74 is increased, thereby lowering an implantation efficiency of oxygen (O) ion to the second side wall surface 15c shown through the second opening 16B. The second etching mask 74 is a mask formed by polysilicon film and is formed in the bottom portion 15A of the first groove 15.

When the implantation angle β is more than 5°, oxygen (O) ions cannot be ion-implanted into a lower part of the first side wall surface 15c shown through the second opening 16B. That is, oxygen (O) ions cannot be ion-implanted to the entire second side wall surface 15c shown through the second opening 16B.

The implantation angle β may be appropriately set in consideration of the depth from the top surface 66b of the hard mask 66 to the opening formation regions C and E, the width of the first groove 15 or the like.

By oblique ion implantation, oxygen (O) ions are selectively ion-implanted into the second side wall surface 15c (semiconductor substrate 13), which is shown through the second opening 16B, to form the oxygen introducing region 79. By doing this, it is prevented that oxygen (O) ion is implanted to the first side wall surface 15b which is shown through the first opening 16A and ion-implanted with arsenic (As) ions.

A conductivity type of a part of the semiconductor substrate 13 corresponding to the first side wall surface 15b shown through the first opening 16A is maintained to be the n-type.

Oxygen (O) included in the oxygen introducing region 79 is reacted with silicon (Si) in the semiconductor substrate 13 by heating the semiconductor substrate 13. Thereby, the silicon oxide 78 which has the insulating property and is shown through the second opening 16B is formed in the oxygen introducing region 79.

Then, by performing the same processes as the processes described in the first embodiment with reference to FIG. 15A through 20B, the memory cell array 77 with which the semiconductor device 76 is provided is formed as shown in FIGS. 21A and 21B.

According to the method of forming the semiconductor device 76 of the second embodiment, the oxygen introducing region 79 is formed by implanting oxygen (O) ions into the second side wall surface 15c which is shown through the second opening 16B, through the first groove 15 and the second opening 16B. Then, the semiconductor substrate 13 is heated, thereby forming the silicon oxide 78 in the oxygen introducing region 79. Oxygen (O) ions can be implanted to only the second side wall surface 15c shown through the second opening 16B without being implanted to the first side wall surface 15b which is shown through the first opening 16A and is implanted with arsenic (As) ions.

The buried bit line 21 is formed in the first groove 15 to be in contact with the silicon oxide 78 which is shown through the second opening 16B. Thereby, the buried bit line 21 is electrically separated the semiconductor substrate 13. Also, small leak current can be suppressed by providing the silicon oxide 78. A high-performance memory cell array can be achieved.

According to the method of forming the semiconductor device 76 of the second embodiment, a similar effect to the method of forming the first semiconductor device 10 of the first embodiment can be obtained. Specifically, the buried bit line 21 with a microfine structure can be formed easily in the bottom portion 15A of the first groove 15. Also, the buried bit line 21 is reduced in resistivity by forming the buried bit line 21 using the metal film. A high-performance semiconductor device can be formed.

It is apparent that the present invention is not limited to the above embodiments, but may be modified and changed without departing from the scope and spirit of the invention.

For example, although the DRAM is shown as the semiconductor device 10 and 76 in the first and second embodiment, the present embodiment is not limited thereto. The present embodiment can be applied to semiconductor devices, other than the DRAM, such as a phase-change memory (PRAM), a resistance change memory (ReRAM) and the like, in which the memory cell region is provided with the vertical MOS transistor. An upper impurity diffusion region of the vertical MOS transistor and a memory element are electrically connected to each other.

In the case of the phase-change memory, an element in which a material such as chalcogenide whose resistivity is variable by heat is interposed between electrodes may be used as a memory element, for example. In the case of the resistance change memory, metal oxide whose resistivity is variable by applying electric voltage or electric current may be used for a memory element, for example.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The term “configured” is used to describe a component, section or part of a device includes hardware that is constructed to carry out the desired function.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

What is claimed is:

1. A semiconductor device comprising:
a first semiconductor pillar including a first diffusion region;
a second semiconductor pillar adjacent to the first semiconductor pillar; and
a first wiring between the first and second semiconductor pillars, the first wiring having a first metal surface, the first metal surface having an ohmic contact with the first diffusion region.

2. The semiconductor device according to claim 1, wherein the first wiring has a second metal surface having a Schottky barrier with the second semiconductor pillar.

3. The semiconductor device according to claim 2, wherein the first and second metal surfaces are positioned on opposite sides with respect to the first wiring, and
the first and second metal surfaces are distanced in a first direction perpendicular to a second direction substantially in which the first wiring extends.

4. The semiconductor device according to claim 2, further comprising:
a first insulating film between the first wiring and each of the first and second semiconductor pillars, the first insulating film having a first opening in which the first metal surface is in the ohmic contact with the first diffusion region, and the first insulating film having a second opening in which the second metal surface is in the Schottky barrier with the second semiconductor pillar.

5. The semiconductor device according to claim 1, wherein the first diffusion region is different in conductivity type from the first and second semiconductor pillars.

6. The semiconductor device according to claim 5, wherein the first diffusion region is higher in impurity concentration from the first and second semiconductor pillars.

7. The semiconductor device according to claim 1, wherein the first wiring comprises a first metal layer having the first and second metal surfaces and a second metal layer separated by the first metal layer from the first diffusion region and from the second semiconductor pillar, and
the first metal layer is higher in resistivity than the second metal layer.

8. The semiconductor device according to claim 1, further comprising:
an insulating region in the second semiconductor pillar,
wherein the first wiring has a second metal surface in contact with the insulating region.

9. The semiconductor device according to claim 8, wherein the first and second metal surfaces are positioned on opposite sides with respect to the first wiring, and
the first and second metal surfaces are distanced in a first direction perpendicular to a second direction substantially in which the first wiring extends.

10. The semiconductor device according to claim 8, further comprising:
a second insulating film between the first wiring and each of the first and second semiconductor pillars, the second insulating film having a first opening in which the first metal surface is in the ohmic contact with the first diffusion region, and the first insulating film having a second opening in which the second metal surface is in contact with the insulating region.

11. The semiconductor device according to claim 1, further comprising:
a second diffusion region on the top of the first semiconductor pillar; and
a capacitor coupled to the second diffusion region.

12. A semiconductor device comprising:
a semiconductor substrate having a first groove, the first groove being defined by first and second side surfaces which face to each other;
a first diffusion region in the semiconductor substrate; and
a first wiring between the first and second side surfaces, the first wiring having a first metal surface having an ohmic contact with the first diffusion region.

13. The semiconductor device according to claim 12, wherein the first wiring has a second metal surface having a Schottky barrier with the second side surface.

14. The semiconductor device according to claim 13, further comprising:
a first insulating film between the first wiring and each of the first and second semiconductor pillars, the first insulating film having a first opening in which the first metal surface is in the ohmic contact with the first diffusion region, and the first insulating film having a second opening in which the second metal surface is in the Schottky bather with the second semiconductor pillar.

15. The semiconductor device according to claim 12, further comprising:
an insulating region in the second semiconductor pillar,
wherein the first wiring has a second metal surface in contact with the second insulating film.

16. The semiconductor device according to claim 12, further comprising:
a second insulating film between the first wiring and each of the first and second semiconductor pillars, the second insulating film having a first opening in which the first metal surface is in the ohmic contact with the first diffusion region, and the first insulating film having a second opening in which the second metal surface is in contact with the insulating region.

17. A semiconductor device comprising:
a first pillar including a first conductivity type impurity;
a first impurity region in a side region of the first pillar, the first impurity region including a second conductivity type impurity different in conductivity type from the first conductivity type impurity;
a second impurity region on a top portion of the first pillar, the second impurity region including the second conductivity type impurity;
a second pillar adjacent to the first pillar, the second pillar including the first conductivity type impurity; and
a bit line between the first and second pillars, the bit line being in contact with the first impurity region, the bit line being in contact with the second pillar.

18. The semiconductor device according to claim 17, further comprising:
a capacitor coupled to the second impurity region.

19. The semiconductor device according to claim 17, wherein the bit line includes a metal film in contact with the second pillar.

20. The semiconductor device according to claim 17, wherein the second pillar comprises a semiconductor pillar portion and an insulating region in a side region of the semiconductor pillar portion, the insulating region is in contact with the bit line.
